(19) United States
(12) Patent Application Publication
(10) Pub. No.: US 2024/0106413 A1
(43) Pub. Date: Mar. 28, 2024

(54) HIGH FREQUENCY MODULE AND COMMUNICATION DEVICE

(71) Applicant: Murata Manufacturing Co., Ltd., Kyoto (JP)

(72) Inventors: Shinichiro TAKAYANAGI, Kyoto (JP); Terumichi KITA, Kyoto (JP); Takanori ITO, Kyoto (JP)

(21) Appl. No.: 18/527,826

(22) Filed: Dec. 4, 2023

Related U.S. Application Data
(63) Continuation of application No. PCT/JP2022/023412, filed on Jun. 10, 2022.

(30) Foreign Application Priority Data
Jun. 25, 2021 (JP) 2021-106071

(51) Int. Cl. H03H 9/58; H05K 1/02

(52) U.S. Cl. CPC H03H 9/58; H05K 1/0243; H05K 2201/1003; H05K 2201/1006; H05K 2201/10098

(57) ABSTRACT

The deterioration in characteristics of a filter is reduced. In a high frequency module, the filter includes a first substrate, a first functional electrode provided on the first substrate and forming a part of an antenna end resonator, a second substrate separate from the first substrate, and a second functional electrode provided on the second substrate and forming a part of at least one acoustic wave resonator other than the antenna end resonator among a plurality of acoustic wave resonators. A first electronic component including the first substrate and the first functional electrode is disposed on the first main surface of the mounting substrate. An inductor is adjacent to the first electronic component in a plan view from a thickness direction of the mounting substrate. The inductor does not overlap the antenna end resonator in a side view from a direction of a winding axis of a winding portion.

### CROSS REFERENCE TO RELATED APPLICATION

This is a continuation of International Application No. PCT/JP2022/023412 filed on Jun. 10, 2022 which claims priority from Japanese Patent Application No. 2021-106071 filed on Jun. 25, 2021. The contents of these applications are incorporated herein by reference in their entireties.

### BACKGROUND ART

### Technical Field

The present disclosure generally relates to a high frequency module and a communication device, and more specifically, to a high frequency module including a mounting substrate and a communication device including the high frequency module.

Patent Document 1 discloses a front end module including a substrate (mounting substrate) having a first main surface and a second main surface, a filter disposed on the first main surface of the substrate, and an inductor disposed on the first main surface of the substrate and adjacent to the filter.
Patent Document 1: International Publication No. 2019/065569

### BRIEF SUMMARY

In the existing high frequency module, characteristics of the filter may deteriorate due to the influence of the magnetic field generated by the inductor.

The present disclosure provides a high frequency module and a communication device which can reduce deterioration in characteristics of a filter.

According to an aspect of the present disclosure, a high frequency module includes a mounting substrate, an antenna terminal, a filter, and an inductor. The mounting substrate has a first main surface and a second main surface that are opposite to each other. The antenna terminal is disposed on the mounting substrate. The filter is connected to the antenna terminal. The inductor is disposed on the first main surface of the mounting substrate. The inductor includes a winding portion. The filter includes a plurality of acoustic wave resonators. The plurality of acoustic wave resonators include a plurality of series arm resonators provided on a signal path connected to the antenna terminal, and a plurality of parallel arm resonators connected between the signal path and a ground. When at least one of a series arm resonator, which is closest to the antenna terminal among the plurality of series arm resonators, and a parallel arm resonator, which is closest to the antenna terminal among the plurality of parallel arm resonators, is defined as an antenna end resonator, the filter includes a first substrate, a first functional electrode provided on the first substrate and forming a part of the antenna end resonator, a second substrate separate from the first substrate, and a second functional electrode provided on the second substrate and forming a part of at least one acoustic wave resonator other than the antenna end resonator among the plurality of acoustic wave resonators. A first electronic component including the first substrate and the first functional electrode is disposed on the first main surface of the mounting substrate. A second electronic component including the second substrate and the second functional electrode is disposed on the first main surface of the mounting substrate. A distance between the antenna terminal and the first electronic component is shorter than a distance between the antenna terminal and the second electronic component. The inductor is adjacent to the first electronic component in a plan view from a thickness direction of the mounting substrate. The inductor does not overlap the antenna end resonator in a side view from a direction of a winding axis of the winding portion.

According to an aspect of the present disclosure, a high frequency module includes a mounting substrate, an antenna terminal, a filter, and an inductor. The mounting substrate has a first main surface and a second main surface that are opposite to each other. The antenna terminal is disposed on the mounting substrate. The filter is connected to the antenna terminal. The inductor is disposed on the first main surface of the mounting substrate. The inductor includes a winding portion. The filter includes a plurality of acoustic wave resonators. The plurality of acoustic wave resonators include a plurality of series arm resonators provided on a signal path connected to the antenna terminal, and a plurality of parallel arm resonators connected between the signal path and a ground. When at least one of a series arm resonator, which is closest to the antenna terminal among the plurality of series arm resonators, and a parallel arm resonator, which is closest to the antenna terminal among the plurality of parallel arm resonators, is defined as an antenna end resonator, the filter includes a first substrate, a first functional electrode provided on the first substrate and forming a part of the antenna end resonator, a second substrate separate from the first substrate, and a second functional electrode provided on the second substrate and forming a part of at least one acoustic wave resonator other than the antenna end resonator among the plurality of acoustic wave resonators. A first electronic component including the first substrate and the first functional electrode is disposed on the first main surface of the mounting substrate. A second electronic component including the second substrate and the second functional electrode is disposed on the first main surface of the mounting substrate. A distance between the antenna terminal and the first electronic component is shorter than a distance between the antenna terminal and the second electronic component. The inductor is adjacent to the first electronic component in a plan view from a thickness direction of the mounting substrate. In the inductor, the antenna end resonator does not overlap an inner part of the winding portion of the inductor in a side view from a side opposite to a side of the first electronic component.

According to an aspect of the present disclosure, a communication device includes the high frequency module and a signal processing circuit. The signal processing circuit is connected to the high frequency module.

According to the above aspects of the present disclosure, the high frequency module and the communication device can reduce deterioration in characteristics of the filter.

### BRIEF DESCRIPTION OF THE DRAWINGS

FIG. 1 is a plan view of a high frequency module according to a first embodiment.

FIG. 2 is a sectional view of the high frequency module taken along line X-X in FIG. 1.

FIG. 3A is a circuit diagram of a filter (first filter) in the high frequency module. FIG. 3B is a circuit diagram of a second filter in the high frequency module.

FIG. 4 is a plan view illustrating a first functional electrode in the high frequency module.

FIG. 5 is a sectional view illustrating a first electronic component in the high frequency module.

FIG. 6 is a sectional view illustrating a second electronic component in the high frequency module.

FIG. 7 is a perspective view of an inductor in the high frequency module.

FIG. 8 is a sectional view of the inductor in the high frequency module.

FIG. 9 is a circuit configuration diagram of a communication device including the high frequency module.

FIG. 10 is a plan view illustrating another example of the first functional electrode in the high frequency module.

FIG. 11 is a plan view illustrating still another example of the first functional electrode in the high frequency module.

FIG. 12 is a circuit diagram illustrating an example of the filter in the high frequency module.

FIG. 13 is a circuit diagram illustrating an example of the filter in the high frequency module.

FIG. 14 is a circuit diagram illustrating an example of the filter in the high frequency module.

FIG. 15 is a circuit diagram illustrating an example of the filter in the high frequency module.

FIG. 16 is a circuit diagram illustrating an example of the filter in the high frequency module.

FIG. 17 is a circuit diagram illustrating an example of the filter in the high frequency module.

FIG. 18 is a circuit diagram illustrating an example of the filter in the high frequency module.

FIG. 19 is a sectional view illustrating another example 1 of the first electronic component in the high frequency module.

FIG. 20 is a sectional view illustrating another example 1 of the second electronic component in the high frequency module.

FIG. 21 is a sectional view illustrating another example 2 of the first electronic component in the high frequency module.

FIG. 22 is a sectional view illustrating another example 2 of the second electronic component in the high frequency module.

FIG. 23 is a sectional view illustrating another example 3 of the first electronic component in the high frequency module.

FIG. 24 is a sectional view illustrating another example 3 of the second electronic component in the high frequency module.

FIG. 25 is a perspective view illustrating another example of the inductor in the high frequency module.

FIG. 26 is a sectional view illustrating still another example of the inductor in the high frequency module.

FIG. 27 is a plan view illustrating another example of a high frequency module according to a second embodiment.

FIG. 28 is a plan view illustrating another example of a high frequency module according to a third embodiment.

### DETAILED DESCRIPTION

The drawings referred to in the following first to third embodiments and the like are all schematic drawings, and the ratios of the respective sizes and thicknesses of the constituent elements in the drawings do not necessarily reflect the actual dimensional ratios.

### First Embodiment

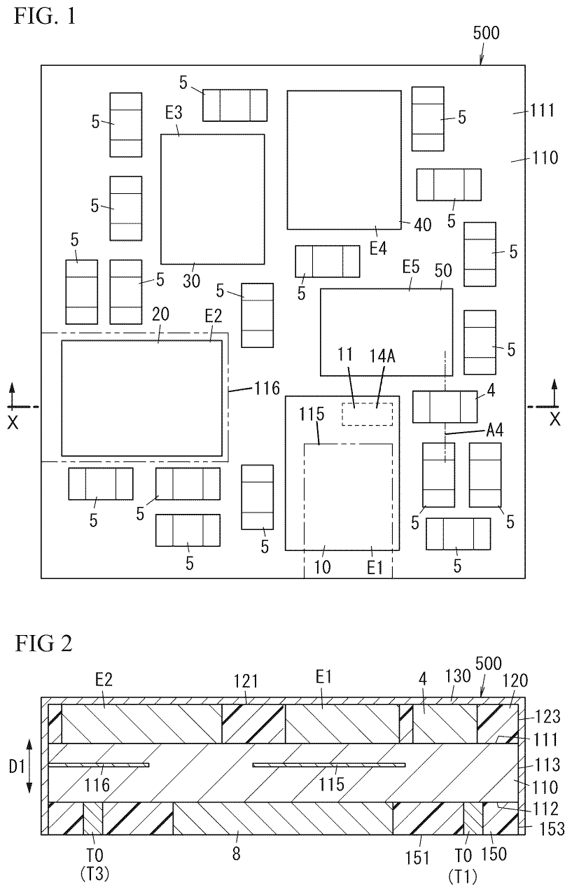

Hereinafter, a high frequency module 500 according to a first embodiment will be described based on FIGS. 1 to 11.

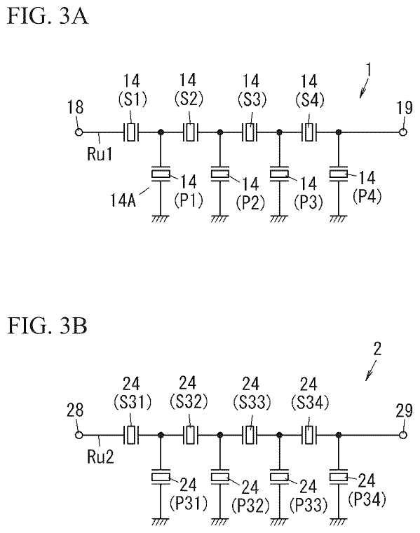

For example, as illustrated in FIGS. 1 and 2, the high frequency module 500 according to the first embodiment includes a mounting substrate 110, an antenna terminal T1 (see FIG. 2), a filter 1 (see FIG. 3A), and an inductor 4. The mounting substrate 110 has a first main surface 111 and a second main surface 112 that are opposite to each other. The antenna terminal T1 is disposed on the mounting substrate 110. The filter 1 is connected to the antenna terminal T1. The fact that “the filter 1 is connected to the antenna terminal T1” means that the filter 1 is directly or indirectly and electrically connected to the antenna terminal T1. An example in which the filter 1 is indirectly and electrically connected to the antenna terminal T1 includes that the filter 1 is electrically connected to the antenna terminal T1 with a conductor electrode, a conductor terminal, wiring, another circuit component, or the like interposed therebetween. The inductor 4 is disposed on the first main surface 111 of the mounting substrate 110. The inductor 4 includes a winding portion 413 (see FIG. 7). The filter 1 has a plurality of acoustic wave resonators 14 (for example, see FIG. 3A). The plurality of acoustic wave resonators 14 include a plurality of (for example, four) series arm resonators S1 to S4 provided on a signal path Ru1 connected to the antenna terminal T1, and a plurality of (for example, four) parallel arm resonators P1 to P4 connected between the signal path Ru1 and a ground. When at least one of the series arm resonators S1, which is closest to the antenna terminal T1 among the plurality of series arm resonators S1 to S4, and the parallel arm resonator P1, which is closest to the antenna terminal T1 among the plurality of parallel arm resonators P1 to P4, is defined as an antenna end resonator 14A, the filter 1 includes a first electronic component E1 having the antenna end resonator 14A and a second electronic component E2 having an acoustic wave resonator 14 other than the antenna end resonator 14A among the plurality of acoustic wave resonators 14. The fact that “the series arm resonator S1, which is closest to the antenna terminal T1” means a series arm resonator that is connected to the antenna terminal T1 with no other series arm resonators S2 to S4 interposed therebetween. The fact that “the parallel arm resonator P1, which is closest to the antenna terminal T1” means a parallel arm resonator that is connected to the antenna terminal T1 with no other series arm resonators S2 to S4 other than the series arm resonator S1 inserted therebetween. The first electronic component E1 is disposed on the first main surface 111 of the mounting substrate 110. The second electronic component E2 is disposed on the first main surface 111 of the mounting substrate 110. A distance between the antenna terminal T1 and the first electronic component E1 is shorter than a distance between the antenna terminal T1 and the second electronic component E2. The inductor 4 is adjacent to the first electronic component E1 in a plan view from a thickness direction D1 (see FIG. 2) of the mounting substrate 110. The fact that “the inductor 4 is adjacent to the first electronic component E1 when in a plan view from the thickness direction D1 of the mounting substrate 110” means that there is no other electronic component between the inductor 4 and the first electronic component E1 and the inductor 4 and the first electronic component E1 are adjacent to each other on the first main surface 111 of the mounting substrate 110 in a plan view from the thickness direction D1 of the mounting substrate 110. A winding axis A4 of the winding portion 413 of the inductor 4 is along the first main surface 111 of the mounting substrate 110. In other words, the winding axis A4 of the winding portion 413 of the inductor 4 is orthogonal to the thickness direction D1 of the mounting substrate 110. The fact that “the winding axis A4 of the winding portion 413 of the inductor 4 is orthogonal to the thickness direction D1 of the mounting substrate 110” means that an angle formed by the thickness direction D1 of the mounting substrate 110 and the winding axis A4 may be within a range of, for example, 80° or greater and 100° or less, without necessarily being limited to a case where the thickness direction D1 of the mounting substrate 110 and the winding axis A4 are strictly orthogonal. The winding axis A4 is a virtual central axis of the winding portion 413. The inductor 4 does not overlap the antenna end resonator 14A when in a side view from a direction of the winding axis A4 of the winding portion 413. The fact that “the inductor 4 does not overlap the antenna end resonator 14A in a side view from a direction of the winding axis A4 of the winding portion 413” means that the inductor 4 does not overlap the first functional electrode 11 of the antenna end resonator 14A when the inductor 4 is orthogonally projected along the winding axis A4, and does not overlap a part overlapping the first functional electrode 11 in the thickness direction D1 of the mounting substrate 110 in the substrate 10.

The high frequency module 500 further includes a second filter 2 (see FIG. 3B) having a second pass band different from a first pass band, which is a pass band of the filter 1 (hereinafter referred to as a first filter 1). A second filter 2 has a plurality of second acoustic wave resonators 24 different from a plurality of first acoustic wave resonators 14, which are the plurality of acoustic wave resonators 14 of the first filter 1. The first pass band includes a frequency band of a first communication band. The second pass band includes a frequency band of a second communication band that enables simultaneous communication with the first communication band. The fact that “ . . . that enables simultaneous communication” means that at least one of simultaneous reception, simultaneous transmission, and simultaneous transmission and reception is possible. In the high frequency module 500, a combination of the first communication band and the second communication band is a combination in which simultaneous reception is performed in the high frequency module 500.

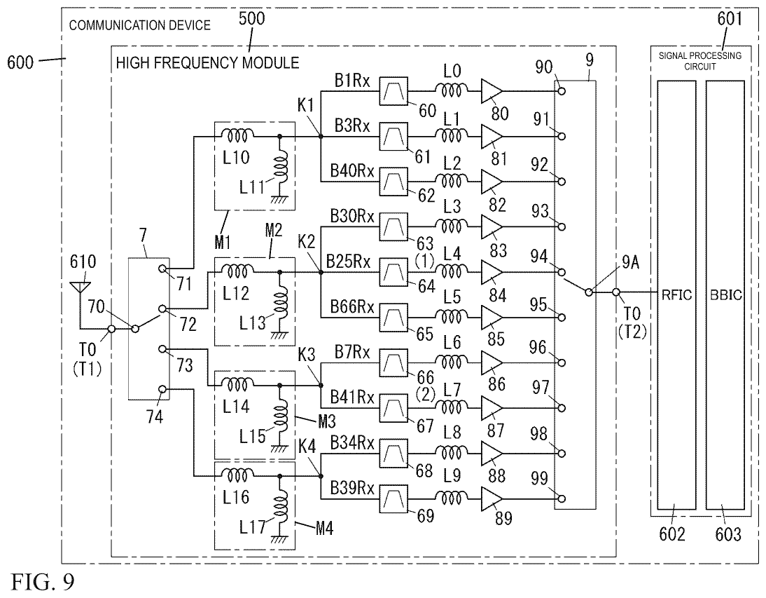

The high frequency module 500 is used, for example, in a communication device 600 as illustrated in FIG. 9. The communication device 600 is, for example, a mobile phone (for example, a smartphone), but is not limited thereto, and may be, for example, a wearable terminal (for example, a smartwatch), or the like. The high frequency module 500 is, for example, a module capable of supporting a fourth generation mobile communication (4G) standard, a fifth generation mobile communication (5G) standard, and the like. The 4G standard is, for example, the third generation partnership project (3GPP) long term evolution (LTE) standard. The 5G standard is, for example, 5G New Radio (NR). The high frequency module 500 is, for example, a module capable of supporting carrier aggregation and dual connectivity. The combination of the first communication band and the second communication band, which enables simultaneous communication, is a combination of a plurality of frequency bands that overlap or do not overlap at all in a part of each other among the frequency bands of the communication band defined by the 3GPP LTE standard and the frequency bands of the communication band defined by the 5G NR standard. The frequency band is a downlink frequency band or an uplink frequency band. The downlink frequency band is a reception band. The uplink frequency band is a transmission band.

Hereinafter, the high frequency module 500 and the communication device 600 according to the first embodiment will be described in more detail with reference to FIGS. 1 to 11.

(1) High Frequency Module

(1.1) Circuit Configuration of High Frequency Module

The circuit configuration of the high frequency module 500 according to the first embodiment will be described with reference to FIG. 9.

The high frequency module 500 is configured, for example, such that it can amplify a reception signal input from an antenna 610 and output the reception signal to a signal processing circuit 601. The signal processing circuit 601 is not a constituent element of the high frequency module 500, but a constituent element of the communication device 600 including the high frequency module 500. The high frequency module 500 is controlled by, for example, the signal processing circuit 601 of the communication device 600.

The high frequency module 500 includes a plurality of (for example, 10) filters 60 to 69, a switch 7 (hereinafter also referred to as a first switch 7), a plurality of (for example, 10) low noise amplifiers 80 to 89, a second switch 9, and a plurality of (for example, 18) inductors L0 to L17. In the high frequency module 500, the filter 63 forms the first filter 1, and the filter 66 forms the second filter 2. In addition, in the high frequency module 500, one inductor adjacent to the first electronic component E1 (see FIG. 1) among the plurality of inductors L0 to L17 forms the inductor 4. In FIG. 1, the inductor other than the inductor 4 among the plurality of inductors L0 to L17 is marked with “5”.

Moreover, the high frequency module 500 includes a plurality of external connection terminals TO as illustrated in FIG. 9. The plurality of external connection terminals TO include the antenna terminal T1, a signal output terminal T2, and a plurality of external ground terminals T3 (see FIG. 2).

The plurality of external ground terminals T3 are, for example, terminals that are electrically connected to a ground electrode of the above-described circuit substrate of the communication device 600 and that is applied with a ground potential.

Hereinafter, a circuit configuration of the high frequency module 500 will be described in more detail.

(1.1.1) Filter

The plurality of filters 60 to 69 are reception filters that have pass bands of frequency bands of the communication bands (downlink frequency bands) that are different from each other. Hereinafter, the downlink frequency band is referred to as a reception band. Each communication band is, for example, a communication band of the 3GPP LTE standard or a communication band of the 5G NR standard.

The filter 60 is, for example, a filter having a pass band that includes a reception band of Band 1 of the 3GPP LTE standard. The filter 61 is, for example, a filter having a pass band that includes a reception band of Band 3 of the 3GPP LTE standard. The filter 62 is, for example, a filter having a pass band that includes a reception band of Band 40 of the 3GPP LTE standard. The filter 63 is, for example, a filter having a pass band that includes the reception band of Band 30 of the 3GPP LTE standard. The filter 64 is, for example, a filter having a pass band that includes a reception band of Band 25 of the 3GPP LTE standard. The filter 65 is, for example, a filter having a pass band that includes the reception band of Band 66 of the 3GPP LTE standard. The filter 66 is, for example, a filter having a pass band that includes a reception band of Band 7 of the 3GPP LTE standard. The filter 67 is, for example, a filter having a pass band that includes the reception band of Band 41 of the 3GPP LTE standard. The filter 68 is, for example, a filter having a pass band that includes the reception band of Band 34 of the 3GPP LTE standard. The filter 69 is, for example, a filter having a pass band that includes the reception band of Band 39 of the 3GPP LTE standard. In FIG. 9, “B1Rx” is written on the left side of the sign of the filter 60 in order to make it easy to understand that the pass band of the filter 60 corresponds to the reception band of Band 1 of the 3GPP LTE standard. Similarly, in FIG. 9, “B3Rx” is written on the left side of the sign of the filter 62 in order to make it easy to understand that the filter 61 corresponds to the reception band of Band 3 of the 3GPP LTE standard. Similarly, in FIG. 9, “B40Rx” is written on the left side of the sign of the filter 62 in order to make it easy to understand that the filter 62 corresponds to the reception band of Band 40 of the 3GPP LTE standard. Similarly, in FIG. 9, “B30Rx” is written on the left side of the sign of the filter 63 in order to make it easy to understand that the filter 63 corresponds to the reception band of Band 30 of the 3GPP LTE standard. Similarly, in FIG. 9, “B25Rx” is written on the left side of the sign of the filter 64 in order to make it easy to understand that the filter 64 corresponds to the reception band of Band 25 of the 3GPP LTE standard. Similarly, in FIG. 9, “B66Rx” is written on the left side of the sign of the filter 65 in order to make it easy to understand that the filter 65 corresponds to the reception band of Band 66 of the 3GPP LTE standard. Similarly, in FIG. 9, “B7Rx” is written on the left side of the sign of the filter 66 in order to make it easy to understand that the filter 66 corresponds to the reception band of Band 7 of the 3GPP LTE standard. Similarly, in FIG. 9, “B41Rx” is written on the left side of the sign of the filter 67 in order to make it easy to understand that the filter 67 corresponds to the reception band of Band 41 of the 3GPP LTE standard. Similarly, in FIG. 9, “B34Rx” is written on the left side of the sign of the filter 68 in order to make it easy to understand that the filter 68 corresponds to the reception band of Band 34 of the 3GPP LTE standard. Similarly, in FIG. 9, “B39Rx” is written on the left side of the sign of the filter 69 in order to make it easy to understand that the filter 69 corresponds to the reception band of Band 39 of the 3GPP LTE standard.

Each of the plurality of filters 60 to 69 is an acoustic wave filter. Hereinafter, the circuit configuration of the first filter 1 (filter 63) among the plurality of filters 60 to 69 will be described with reference to FIG. 3A, and the circuit configuration of the second filter 2 (filter 66) will be described with reference to FIG. 3B. The circuit configurations of the filters 60 to 62, 64, 65, and 67 to 69 are, for example, the same as the first filter 1, but may be different.

As described above, the first filter 1 (see FIG. 3A) has a plurality of (for example, four) first acoustic wave resonators 14. The plurality of first acoustic wave resonators 14 include an antenna end resonator 14A. The first filter 1 is, for example, a ladder filter, and includes four series arm resonators S1 to S4 provided on a signal path Ru1 (hereinafter also referred to as a first signal path Ru1), and four parallel arm resonators P1 to P4 provided between the first signal path Ru1 and a ground. The four series arm resonators S1 to S4 are connected in series on the first signal path Ru1. The first filter 1 has two input/output terminals 18 and 19. The input/output terminal 18 is, for example, an input terminal. The input/output terminal 19 is, for example, an output terminal. In the first filter 1, four series arm resonators S1 to S4 are arranged on the first signal path Ru1 in order of the series arm resonator S1, the series arm resonator S2, the series arm resonator S3, and the series arm resonator S4 from a side of the input/output terminal 18. The parallel arm resonator P1 is connected between a part between two series arm resonators S1 and S2 on the first signal path Ru1 and the ground. The parallel arm resonator P2 is connected between a part between two series arm resonators S2 and S3 on the first signal path Ru1 and the ground. The parallel arm resonator P3 is connected between a part between two series arm resonators S3 and S4 on the first signal path Ru1 and the ground. The parallel arm resonator P4 is connected between a part between the series arm resonator S4 and the input/output terminal 19 of the first filter 1 on the first signal path Ru1 and the ground.

As described above, the second filter 2 (see FIG. 3B) has a plurality of second acoustic wave resonators 24. The second filter 2 is, for example, a ladder filter, and includes four series arm resonators S31 to S34 provided on a second signal path Ru2, and four parallel arm resonators P31 to P34 provided between the second signal path Ru2 and the ground. The four series arm resonators S31 to S34 are connected in series on the second signal path Ru2. The second filter 2 has two input/output terminals 28 and 29. The input/output terminal 28 is, for example, an input terminal. The input/output terminal 29 is, for example, an output terminal. In the second filter 2, four series arm resonators S31 to S34 are arranged on the second signal path Ru2 in order of the series arm resonator S31, the series arm resonator S32, the series arm resonator S33, and the series arm resonator S34 from a side of the input/output terminal 28. The parallel arm resonator P31 is connected between a part between two series arm resonators S31 and S32 on the second signal path Ru2 and the ground. The parallel arm resonator P32 is connected between a part between two series arm resonators S32 and S33 on the second signal path Ru2 and the ground. The parallel arm resonator P33 is connected between a part between two series arm resonators S33 and S34 on the second signal path Ru2 and the ground. The parallel arm resonator P34 is connected between a part between the series arm resonator S34 and the input/output terminal 29 on the second signal path Ru2 and the ground.

(1.1.2) First Switch

As illustrated in FIG. 9, the first switch 7 has a common terminal 70 and a plurality of (four in the illustrated example) selection terminals 71 to 74. The common terminal 70 is connected to the antenna terminal T1. The selection terminal 71 is connected to a connection point K1 between the filter 60, the filter 61, and the filter 62 with a matching circuit M1 interposed therebetween. The matching circuit M1 includes an inductor L10 and an inductor L11. In addition, the selection terminal 72 is connected to a connection point K2 between the filter 63, the filter 64, and the filter 65 with a matching circuit M2 interposed therebetween. The matching circuit M2 includes an inductor L12 and an inductor L13. Further, the selection terminal 73 is connected to a connection point K3 between the filter 66 and the filter 67 with the matching circuit M3 interposed therebetween. The matching circuit M3 includes an inductor L14 and an inductor L15. The selection terminal 74 is connected to a connection point K4 between the filter 68 and the filter 69. A matching circuit M4 includes an inductor L16 and an inductor L17. The first switch 7 is, for example, a switch that can connect at least one or more of the four selection terminals 71 to 74 to the common terminal 70. In this case, the first switch 7 is, for example, a switch that can be connected in a one-to-one manner and a one-to-many manner. The matching circuits M1 to M4 are circuits for impedance matching.

The first switch 7 is controlled by, for example, the signal processing circuit 601. The first switch 7 switches a connection state between the common terminal 70 and the four selection terminals 71 to 74 in response to a control signal from an RF signal processing circuit 602 of the signal processing circuit 601.

(1.1.3) Low Noise Amplifier

Each of the plurality of low noise amplifiers 80 to 89 has an input terminal and an output terminal. Each of the plurality of low noise amplifiers 80 to 89 amplifies the reception signal input to the input terminal to output the reception signal from the output terminal. The input terminal of the low noise amplifier 80 is connected to the filter 60 with the inductor L0 for impedance matching interposed therebetween. The input terminal of the low noise amplifier 81 is connected to the filter 61 with the inductor L1 for impedance matching interposed therebetween. The input terminal of the low noise amplifier 82 is connected to the filter 62 with the inductor L2 for impedance matching interposed therebetween. The input terminal of the low noise amplifier 83 is connected to the filter 63 with the inductor L3 for impedance matching interposed therebetween. The input terminal of the low noise amplifier 84 is connected to the filter 64 with the inductor L4 for impedance matching interposed therebetween. The input terminal of the low noise amplifier 85 is connected to the filter 65 with the inductor L5 for impedance matching interposed therebetween. The input terminal of the low noise amplifier 86 is connected to the filter 66 with the inductor L6 for impedance matching interposed therebetween. The input terminal of the low noise amplifier 87 is connected to the filter 67 with the inductor L7 for impedance matching interposed therebetween. The input terminal of the low noise amplifier 88 is connected to the filter 68 with the inductor L8 for impedance matching interposed therebetween. The input terminal of the low noise amplifier 89 is connected to the filter 69 with the inductor L9 for impedance matching interposed therebetween.

The output terminals of the plurality of low noise amplifiers 80 to 89 are connected to the signal output terminal T2 with the second switch 9 interposed therebetween. Therefore, the plurality of low noise amplifiers 80 to 89 are connected to the signal processing circuit 601 with the signal output terminal T2 interposed therebetween. The signal output terminal T2 is a terminal for outputting high frequency signals (reception signals) from the plurality of low noise amplifiers 80 to 89 to an external circuit (for example, the signal processing circuit 601).

(1.1.4) Second Switch

The second switch 9 has a common terminal 9A and a plurality of (10 in the illustrated example) selection terminals 90 to 99. The common terminal 9A is connected to the signal output terminal T2. The plurality of selection terminals 90 to 99 are connected to the output terminals of the plurality of low noise amplifiers 80 to 89 in a one-to-one manner. The second switch 9 is, for example, a switch that can connect the common terminal 9A and at least one or more of the plurality of selection terminals 90 to 99. In this case, the second switch 9 is, for example, a switch that can be connected in a one-to-one manner and a one-to-many manner.

The second switch 9 is controlled by, for example, the signal processing circuit 601. The second switch 9 switches a connection state between the common terminal 9A and the plurality of selection terminals 90 to 99 in response to the control signal from the RF signal processing circuit 602 of the signal processing circuit 601.

(1.2) Structure of High Frequency Module

Hereinafter, a structure of the high frequency module 500 will be described with reference to FIGS. 1 to 9.

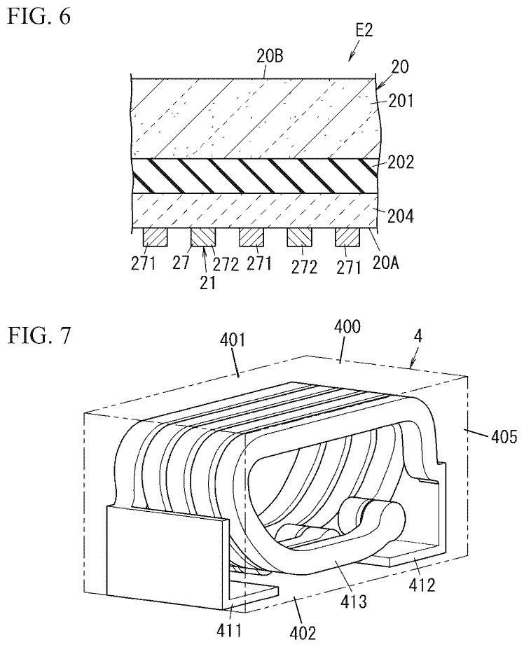

The high frequency module 500 includes the mounting substrate 110, the plurality of (for example, 10) filters 60 to 69 (see FIG. 6), and the plurality of (for example, 18) inductors L0 to L17. In addition, the high frequency module 500 includes an IC chip 8 (see FIG. 2). The IC chip 8 includes the plurality of (for example, 10) low noise amplifiers 80 to 89 (see FIG. 9) and the second switch 9 (see FIG. 9). In addition, as illustrated in FIG. 2, the high frequency module 500 includes the plurality of external connection terminals TO, a resin layer 120 (hereinafter also referred to as a first resin layer 120), a second resin layer 150, and a metal electrode layer 130. The plurality of filters 60 to 69 include the first filter 1 (for example, the filter 63) and the second filter 2 (for example, the filter 66). The plurality of inductors L0 to L17 include the above-described inductor 4 (see FIGS. 1, 2, 7, and 8). FIG. 1 does not illustrate the first resin layer 120 and a metal electrode layer 130.

(1.2.1) Mounting Substrate

As illustrated in FIG. 2, the mounting substrate 110 has the first main surface 111 and the second main surface 112 that are opposite to each other in the thickness direction D1 of the mounting substrate 110. The mounting substrate 110 includes a plurality of dielectric layers, a plurality of conductive layers, and a plurality of via conductors. In the mounting substrate 110, the plurality of dielectric layers and the plurality of conductive layers are alternately laminated one by one in the thickness direction D1 of the mounting substrate 110. That is, the mounting substrate 110 is a multilayer substrate including the plurality of dielectric layers and the plurality of conductive layers. The plurality of conductive layers are formed in a predetermined pattern determined for each layer. Each of the plurality of conductive layers includes one or more conductor portions. The mounting substrate 110 is, for example, a low temperature co-fired ceramics (LTCC) substrate. When the mounting substrate 110 is an LTCC substrate, a material of each dielectric layer is, for example, ceramic containing alumina and glass. In addition, a material of each conductive layer is, for example, copper. The material of each conductive layer is not limited to copper, and may be, for example, silver. The mounting substrate 110 is not limited to an LTCC substrate, but may be, for example, a printed wiring board, a high temperature co-fired ceramics (HTCC) substrate, or a resin multilayer substrate.

The first main surface 111 and the second main surface 112 of the mounting substrate 110 are separated in the thickness direction D1 of the mounting substrate 110, and intersect with each other in the thickness direction D1 of the mounting substrate 110. The first main surface 111 of the mounting substrate 110 includes a surface that is orthogonal to the thickness direction D1 of the mounting substrate 110 and a surface that is not orthogonal to the thickness direction D1. In addition, for example, the second main surface 112 of the mounting substrate 110 is orthogonal to the thickness direction D1 of the mounting substrate 110, but may include, for example, a side surface of the conductor portion or the like, as a surface that is not orthogonal to the thickness direction D1.

In one of the plurality of conductive layers, the plurality of conductor portions include a first ground conductor portion 115 and a second ground conductor portion 116. The first ground conductor portion 115 and the second ground conductor portion 116 may be provided in conductive layers different from each other. As illustrated in FIG. 1, the first ground conductor portion 115 and the second ground conductor portion 116 have a quadrangle shape in a plan view from the thickness direction D1 of the mounting substrate 110, but the present disclosure is not limited thereto. The first ground conductor portion 115 and the second ground conductor portion 116 are circuit grounds of the high frequency module 500.

The first ground conductor portion 115 is connected to the external ground terminal T3 with the via conductor or the like interposed therebetween. The second ground conductor portion 116 is connected to the external ground terminal T3 with the via conductor or the like interposed therebetween. In addition, the first ground conductor portion 115 and the second ground conductor portion 116 are electrically connected to the metal electrode layer 130. The first ground conductor portion 115 and the second ground conductor portion 116 are in contact with the metal electrode layer 130.

(1.2.2) Electronic Component

As illustrated in FIGS. 1 and 2, in the high frequency module 500, a plurality of (for example, 22) electronic components (first electronic component E1, second electronic component E2, third electronic component E3, fourth electronic component E4, fifth electronic component E5, and inductors L0 to L17) are mounted on the first main surface 111 of the mounting substrate 110, and one electronic component (IC chip 8) is mounted on the second main surface 112 of the mounting substrate 110. The fact that “the electronic components are mounted on the first main surface 111 of the mounting substrate 110” means that the electronic components are disposed on (mechanically connected to) the first main surface 111 of the mounting substrate 110 and the electronic components are electrically connected to the (appropriate conductor portion of) mounting substrate 110. The fact that “the electronic components are mounted on the second main surface 112 of the mounting substrate 110” means that the electronic components are disposed on (mechanically connected to) the second main surface 112 of the mounting substrate 110 and the electronic components are electrically connected to the (appropriate conductor portion of) mounting substrate 110. The first electronic component E1 includes the antenna end resonator 14A (for example, the parallel arm resonator P1) of the first filter 1 (for example, the filter 63), the second filter 2 (for example, the filter 66), and the filter 67. The second electronic component E2 includes the first acoustic wave resonators 14 (the series arm resonators S1 to S4 and the parallel arm resonators P2 to P4) other than the antenna end resonator 14A among the plurality of first acoustic wave resonators 14 of the first filter 1. In addition, the second electronic component E2 includes the filter 62. The third electronic component E3 includes the filter 60 and the filter 65. The fourth electronic component E4 includes the filter 61 and the filter 64. The fifth electronic component E5 includes the filter 68 and the filter 69.

As illustrated in FIG. 1, an outer edge of each of the first electronic component E1, the second electronic component E2, the third electronic component E3, the fourth electronic component E4, and the fifth electronic component E5 has a quadrangle shape, in a plan view from the thickness direction D1 of the mounting substrate 110. In addition, an outer edge of each of the plurality of inductors L0 to L17 has a quadrangle shape in a plan view from the thickness direction D1 of the mounting substrate 110. As described above, in FIG. 1, the inductor other than the inductor 4 among the plurality of inductors L0 to L17 is marked with “5”. An outer edge of the IC chip 8 has a quadrangle shape in a plan view from the thickness direction D1 of the mounting substrate 110.

The first electronic component E1 includes the antenna end resonator 14A of the first filter 1 (for example, the filter 63), as described above. In addition, the first electronic component E1 includes the second filter 2 (for example, the filter 66) and the filter 67, but the present disclosure is not limited thereto, and the first electronic component E1 may include at least the antenna end resonator 14A of the first filter 1.

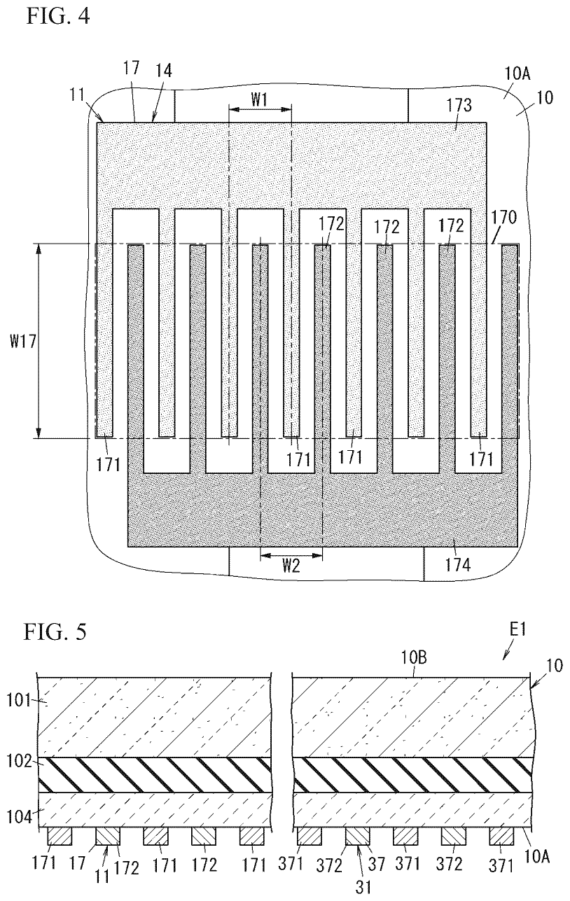

As illustrated in FIGS. 4 to 6, the first filter 1 includes a first substrate (substrate 10), the first functional electrode 11, and a second substrate (substrate 20) separate from the first substrate (substrate 10), and at least one (for example, seven) second functional electrode 21. FIG. 6 illustrates only one second functional electrode 21 among the seven second functional electrodes 21. As illustrated in FIGS. 4 and 5, the first functional electrode 11 is provided on the first substrate (substrate 10), and forms a part of the antenna end resonator 14A. As illustrated in FIG. 6, the seven second functional electrodes 21 are provided on the second substrate (substrate 20), and form a part of each of seven acoustic wave resonators 14 other than the antenna end resonator 14A among eight acoustic wave resonators 14.

In the high frequency module 500, the first filter 1 is an acoustic wave filter that uses surface acoustic waves, and the first functional electrode 11 includes an interdigital transducer (IDT) electrode 17. The IDT electrode 17 includes a plurality of first electrode fingers 171, a plurality of second electrode fingers 172, a first busbar 173 to which the plurality of first electrode fingers 171 are connected, and a second busbar 174 to which the plurality of second electrode fingers 172 are connected. In the first filter 1, the antenna end resonator 14A includes the IDT electrode 17 and a part of the first substrate (substrate 10). The IDT electrode 17 has an intersection region 170 defined by the plurality of first electrode fingers 171 and the plurality of second electrode fingers 172. The intersection region 170 is a region between an envelope of tips of the plurality of first electrode fingers 171 and an envelope of tips of the plurality of second electrode fingers 172. The IDT electrode 17 excites acoustic waves in the intersection region 170. The characteristics of the first filter 1 can be changed, for example, by appropriately changing an electrode finger pitch of the IDT electrode 17 of the first functional electrode 11, an intersecting width W17 that is a width of the intersection region 170 of the IDT electrode 17, a material of the first substrate (substrate 10), and the like. The electrode finger pitch of the IDT electrode 17 is a distance W1 between center lines of two adjacent first electrode fingers 171 among the plurality of first electrode fingers 171 or a distance W2 between center lines of two adjacent second electrode fingers 172 among the plurality of second electrode fingers 172.

Each of the seven second functional electrodes 21 includes an IDT electrode 27 (see FIG. 6). The IDT electrode 27 includes a plurality of first electrode fingers 271, a plurality of second electrode fingers 272, a first busbar (not illustrated) to which the plurality of first electrode fingers 271 are connected, and a second busbar (not illustrated) to which the plurality of second electrode fingers 272 are connected. In the first filter 1, each of the seven acoustic wave resonators 14 other than the antenna end resonator 14A among the plurality of acoustic wave resonators 14 includes the IDT electrode 27 and a part of the second substrate (substrate 20). The IDT electrode 27 has an intersection region (not illustrated) defined by the plurality of first electrode fingers 271 and the plurality of second electrode fingers 272. The intersection region is a region between an envelope of tips of the plurality of first electrode fingers 271 and an envelope of tips of the plurality of second electrode fingers 272. The IDT electrode 27 excites acoustic waves in the intersection region. The characteristics of the first filter 1 can be changed, for example, by appropriately changing an electrode finger pitch of the IDT electrode 27 of the second functional electrode 21, an intersecting width that is a width of the intersection region of the IDT electrode 27, a material of the second substrate (substrate 20), and the like. The electrode finger pitch of the IDT electrode 27 is a distance between center lines of two adjacent first electrode fingers 271 among the plurality of first electrode fingers 271 or a distance between center lines of two adjacent second electrode fingers 272 among the plurality of second electrode fingers 272.

As illustrated in FIG. 5, the second filter 2 includes a third substrate (substrate 10), and a plurality of third functional electrodes 31 provided on the third substrate and forming a part of each of the plurality of (for example, eight) second acoustic wave resonators 24. FIG. 5 illustrates only one third functional electrode 31 among the plurality of third functional electrodes 31. In the high frequency module 500, the second filter 2 is an acoustic wave filter that uses surface acoustic waves, and each of the plurality of third functional electrodes 31 includes an IDT electrode 37. The IDT electrode 37 includes a plurality of first electrode fingers 371, a plurality of second electrode fingers 372, a first busbar (not illustrated) to which the plurality of first electrode fingers 371 are connected, and a second busbar (not illustrated) to which the plurality of second electrode fingers 372 are connected. In the second filter 2, each of the plurality of second acoustic wave resonators 24 includes the IDT electrode 37 and a part of the third substrate. The IDT electrode 37 has an intersection region (not illustrated) defined by the plurality of first electrode fingers 371 and the plurality of second electrode fingers 372. The intersection region is a region between an envelope of tips of the plurality of first electrode fingers 371 and an envelope of tips of the plurality of second electrode fingers 372. The IDT electrode 37 excites acoustic waves in the intersection region. The characteristics of the second filter 2 can be changed, for example, by appropriately changing an electrode finger pitch of the IDT electrode 37 of the third functional electrode 31, an intersecting width of the intersection region of the IDT electrode 37, a material of the third substrate (substrate 10), and the like.

In the first electronic component E1, the first substrate is common to the third substrate. In other words, in the first electronic component E1, the first substrate and the third substrate are the same substrate 10. An outer edge of the substrate 10 has an oblong shape in a plan view from the thickness direction D1 of the mounting substrate 110, but the present disclosure is not limited thereto.

Moreover, the first electronic component E1 includes the filter 67 as described above. The filter 67 includes a fourth substrate, and a plurality of functional electrodes provided on the fourth substrate and forming a part of each of the plurality of acoustic wave resonators in the filter 67. In the high frequency module 500, the filter 67 is an acoustic wave filter that uses surface acoustic waves, and each of the plurality of functional electrodes forming a part of each of the plurality of acoustic wave resonators in the filter 67 includes an IDT electrode. In the first electronic component E1, the first substrate, the third substrate, and the fourth substrate are common. In other words, the first substrate, the third substrate, and the fourth substrate are the same substrate 10.

Moreover, the second electronic component E2 includes the plurality of acoustic wave resonators 14 other than the antenna end resonator 14A of the first filter 1 (for example, the filter 63) and the filter 62, but the present disclosure is not limited thereto, and the second electronic component E2 may include at least one acoustic wave resonator 14.

The filter 62 includes a fifth substrate, and a plurality of functional electrodes provided on the fifth substrate and forming a part of each of the plurality of acoustic wave resonators in the filter 62. In the high frequency module 500, the filter 62 is an acoustic wave filter that uses surface acoustic waves, and each of the plurality of functional electrodes forming a part of each of the plurality of acoustic wave resonators in the filter 62 includes an IDT electrode.

In the second electronic component E2, the second substrate is common to the fifth substrate. In other words, in the second electronic component E2, the second substrate and the fifth substrate are the same substrate 20. An outer edge of the substrate 20 has an oblong shape in a plan view from the thickness direction D1 of the mounting substrate 110, but the present disclosure is not limited thereto.

As illustrated in FIG. 5, the first substrate (substrate 10) includes a piezoelectric layer 104 (hereinafter also referred to as the first piezoelectric layer 104), and a high velocity member 101 (hereinafter also referred to as the first high velocity member 101). The first high velocity member 101 is a high velocity support substrate located on a side opposite to the first functional electrode 11 with the first piezoelectric layer 104 interposed therebetween. In the first high velocity member 101, a velocity of a bulk wave propagating through the first high velocity member 101 is faster than a velocity of an acoustic wave propagating through the first piezoelectric layer 104. In this case, the bulk wave propagating through the first high velocity member 101 is a bulk wave having the lowest velocity among the plurality of bulk waves propagating through the first high velocity member 101. The first substrate (substrate 10) further includes a low velocity film 102 (hereinafter also referred to as a first low velocity film 102) interposed between the first high velocity member 101 and the first piezoelectric layer 104. The first low velocity film 102 is a film in which the velocity of the bulk wave propagating through the first low velocity film 102 is slower than the velocity of the bulk wave propagating through the first piezoelectric layer 104.

As illustrated in FIG. 6, the second substrate (substrate 20) includes a piezoelectric layer 204 (hereinafter also referred to as the second piezoelectric layer 204), and a high velocity member 201 (hereinafter also referred to as the second high velocity member 201). The second high velocity member 201 is a high velocity support substrate located on a side opposite to the second functional electrode 21 with the second piezoelectric layer 204 interposed therebetween. In the second high velocity member 201, a velocity of a bulk wave propagating through the second high velocity member 201 is faster than a velocity of an acoustic wave propagating through the second piezoelectric layer 204. In this case, the bulk wave propagating through the second high velocity member 201 is a bulk wave having the lowest velocity among the plurality of bulk waves propagating through the second high velocity member 201. The second substrate (substrate 20) further includes a low velocity film 202 (hereinafter also referred to as a second low velocity film 202) interposed between the second high velocity member 201 and the second piezoelectric layer 204. The second low velocity film 202 is a film in which the velocity of the bulk wave propagating through the second low velocity film 202 is slower than the velocity of the bulk wave propagating through the second piezoelectric layer 204.

A material of each of the first piezoelectric layer 104 and the second piezoelectric layer 204 is, for example, lithium tantalate or lithium niobate.

The material of the first high velocity member 101 and the second high velocity member 201 are, for example, silicon. The material of the first high velocity member 101 and the second high velocity member 201 may contain, for example, at least one material selected from the group consisting of silicon, aluminum nitride, aluminum oxide, silicon carbide, silicon nitride, sapphire, lithium tantalate, lithium niobate, crystal, alumina, zirconia, cordierite, mullite, steatite, forsterite, magnesia, and diamond.

A material of the first low velocity film 102 and the second low velocity film 202 is, for example, silicon oxide. The material of the first low velocity film 102 and the second low velocity film 202 is not limited to silicon oxide. The material of the first low velocity film 102 and the second low velocity film 202 may be, for example, silicon oxide, glass, silicon oxynitride, tantalum oxide, a compound in which fluorine, carbon, or boron is added to silicon oxide, or a material having each of the above materials as a main component.

Each of the first electronic component E1 and the second electronic component E2 is a chip (also referred to as a die), but is not limited thereto, and may have a chip and a package structure provided on the chip. The package structure of the first electronic component E1 includes, for example, a first spacer layer having a first main surface 10A and a second main surface 10B and disposed on the first main surface 10A of the substrate 10 (see FIG. 5), a first cover member disposed on the first spacer layer to be opposite to the substrate 10 in a thickness direction of the substrate 10, and a plurality of first external terminals. The package structure of the second electronic component E2 includes, for example, a second spacer layer having a first main surface 20A and a second main surface 20B and disposed on the first main surface 20A of the substrate 20 (see FIG. 6), a second cover member disposed on the second spacer layer to be opposite to the substrate 20 in a thickness direction of the substrate 20, and a plurality of second external terminals. The first spacer layer and the second spacer layer have electrical insulating properties. A material of the first spacer layer and the second spacer layer is epoxy resin, polyimide, or the like. The first cover member and the second cover member have a flat plate shape. The first cover member overlaps the plurality of first functional electrodes 11 and third functional electrodes 31 in the thickness direction of the substrate 10, and is separated from the plurality of first functional electrode 11 and the plurality of third functional electrodes 31 in the thickness direction of the substrate 10. The second cover member overlaps the plurality of second functional electrodes 21 in the thickness direction of the substrate 20, and is separated from the plurality of second functional electrodes 21 in the thickness direction of the substrate 20. The first cover member and the second cover member have electrical insulating properties. A material of the first cover member and the second cover member is epoxy resin, polyimide, or the like. When the first electronic component E1 has a package structure, the plurality of first external terminals are configured to be exposed from the first cover member. When the second electronic component E2 has a package structure, the plurality of second external terminals are configured to be exposed from the second cover member. Each of the plurality of first external terminals and the plurality of second external terminals includes a conductive bump. A material of the conductive bump is, for example, solder, gold, or copper. The first electronic component E1 is mounted on the first main surface 111 of the mounting substrate 110 such that the second main surface 10B of the substrate 10 is located on a side opposite to a side of the mounting substrate 110, regardless of the presence or absence of the package structure. In other words, in the first electronic component E1, the plurality of first external terminals are electrically connected to the plurality of conductor portions that overlap the plurality of first external terminals, respectively, on the mounting substrate 110. In addition, the second electronic component E2 is mounted on the first main surface 111 of the mounting substrate 110 such that the second main surface 20B of the substrate 20 is located on the side opposite to the side of the mounting substrate 110, regardless of the presence or absence of the package structure. In other words, in the second electronic component E2, the plurality of second external terminals are electrically connected to the plurality of conductor portions that overlap the plurality of second external terminals, respectively, on the mounting substrate 110. The plurality of first external terminals include, for example, the connection terminal connected to the antenna end resonator 14A of the first filter 1 (filter 63), the input terminal (input/output terminal 28) of the second filter 2 (filter 66), the output terminal (input/output terminal 29) of the second filter 2 (filter 66), the input terminal of the filter 67, the output terminal of the filter 67, and the plurality of ground terminals. The plurality of second external terminals include, for example, the connection terminal connected to the antenna end resonator 14A of the first filter 1 (filter 63), (for example, the input/output terminal 18 of the first filter), the output terminal (input/output terminal 19) of the first filter 1 (filter 63), the input terminal of the filter 62, the output terminal of the filter 62, and the plurality of ground terminals.

The third electronic component E3 includes the filter 60 and the filter 65 (see FIGS. 1 and 9). The filter 60 includes a sixth substrate, and a plurality of functional electrodes provided on the sixth substrate and forming a part of each of the plurality of acoustic wave resonators in the filter 60. In the high frequency module 500, the filter 60 is an acoustic wave filter that uses surface acoustic waves, and each of the plurality of functional electrodes forming a part of each of the plurality of acoustic wave resonators in the filter 60 includes an IDT electrode. The filter 65 includes a seventh substrate, and a plurality of functional electrodes provided on the seventh substrate and forming a part of each of the plurality of acoustic wave resonators in the filter 65. In the high frequency module 500, the filter 65 is an acoustic wave filter that uses surface acoustic waves, and each of the plurality of functional electrodes forming a part of each of the plurality of acoustic wave resonators in the filter 65 includes an IDT electrode.

In the third electronic component E3, the sixth substrate is common to the seventh substrate. In other words, in the third electronic component E3, the sixth substrate and the seventh substrate are the same substrate 30 (see FIG. 1). An outer edge of the substrate 30 has an oblong shape in a plan view from the thickness direction D1 of the mounting substrate 110, but the present disclosure is not limited thereto. The substrate 30 has, for example, the same structure as the substrate 10 or the substrate 20. The third electronic component E3 is a chip (also referred to as a die), but is not limited thereto, and may have a chip and a package structure provided on the chip. The third electronic component E3 has a plurality of third external terminals. The plurality of third external terminals include, for example, the input terminal of the filter 60, the output terminal of the filter 60, the input terminal of the filter 65, the output terminal of the filter 65, and the plurality of ground terminals.

The fourth electronic component E4 includes the filter 61 and the filter 64 (see FIGS. 1 and 9). The filter 61 includes an eighth substrate, and a plurality of functional electrodes provided on the eighth substrate and forming a part of each of the plurality of acoustic wave resonators in the filter 61. In the high frequency module 500, the filter 61 is an acoustic wave filter that uses surface acoustic waves, and each of the plurality of functional electrodes forming a part of each of the plurality of acoustic wave resonators in the filter 61 includes an IDT electrode. The filter 64 includes a ninth substrate, and a plurality of functional electrodes provided on the ninth substrate and forming a part of each of the plurality of acoustic wave resonators in the filter 64. In the high frequency module 500, the filter 64 is an acoustic wave filter that uses surface acoustic waves, and each of the plurality of functional electrodes forming a part of each of the plurality of acoustic wave resonators in the filter 64 includes an IDT electrode.

In the fourth electronic component E4, the eighth substrate is common to the ninth substrate. In other words, in the fourth electronic component E4, the eighth substrate and the ninth substrate are the same substrate 40 (see FIG. 1). An outer edge of the substrate 40 has an oblong shape in a plan view from the thickness direction D1 of the mounting substrate 110, but the present disclosure is not limited thereto. The substrate 40 has, for example, the same structure as the substrate 10 or the substrate 20. The fourth electronic component E4 is a chip (also referred to as a die), but is not limited thereto, and may have a chip and a package structure provided on the chip. The fourth electronic component E4 has a plurality of fourth external terminals. The plurality of fourth external terminals include, for example, the input terminal of the filter 61, the output terminal of the filter 61, the input terminal of the filter 64, the output terminal of the filter 64, and the plurality of ground terminals.

The fifth electronic component E5 includes the filter 68 and the filter 69 (see FIGS. 1 and 9). The filter 68 includes a tenth substrate, and a plurality of functional electrodes provided on the tenth substrate and forming a part of each of the plurality of acoustic wave resonators in the filter 68. In the high frequency module 500, the filter 68 is an acoustic wave filter that uses surface acoustic waves, and each of the plurality of functional electrodes forming a part of each of the plurality of acoustic wave resonators in the filter 68 includes an IDT electrode. The filter 69 includes an eleventh substrate, and a plurality of functional electrodes provided on the eleventh substrate and forming a part of each of the plurality of acoustic wave resonators in the filter 69. In the high frequency module 500, the filter 69 is an acoustic wave filter that uses surface acoustic waves, and each of the plurality of functional electrodes forming a part of each of the plurality of acoustic wave resonators in the filter 69 includes an IDT electrode.

In the fifth electronic component E5, the tenth substrate is common to the eleventh substrate. In other words, in the fifth electronic component E5, the tenth substrate and the eleventh substrate are the same substrate 50 (see FIG. 1). An outer edge of the substrate 50 has an oblong shape in a plan view from the thickness direction D1 of the mounting substrate 110, but the present disclosure is not limited thereto. The substrate 50 has, for example, the same structure as the substrate 10 or the substrate 20. The fifth electronic component E5 is a chip (also referred to as a die), but is not limited thereto, and may have a chip and a package structure provided on the chip. The fifth electronic component E5 has a plurality of fifth external terminals. The plurality of fifth external terminals include, for example, the input terminal of the filter 68, the output terminal of the filter 68, the input terminal of the filter 69, the output terminal of the filter 69, and the plurality of ground terminals.

The IC chip 8 (see FIG. 2) is, for example, a Si-based IC chip including the first switch 7, the plurality of (for example, 10) low noise amplifiers 80 to 89, and the second switch 9. An outer edge of the IC chip 8 has an oblong shape in a plan view from the thickness direction D1 of the mounting substrate 110, but the present disclosure is not limited thereto.

Each of the plurality of inductors L0 to L17 (see FIG. 9) is a chip inductor. Therefore, each of the plurality of (for example, 18) inductors L0 to L7 is a surface mount device (SMD). As described above, in the high frequency module 500, one inductor adjacent to the first electronic component E1 among the plurality of inductors L0 to L17 forms the inductor 4, and in FIG. 1, the inductor other than the inductor 4 among the plurality of inductors L0 to L17 is marked with “5”. Hereinafter, in the plurality of (for example, 18) inductors L0 to L17, the plurality of (for example, 17) inductors marked with “5” in FIG. 1 are also referred to as the plurality of (for example, 17) inductors 5. Each of the inductors 4 and plurality of inductors 5 has a rectangular parallelepiped shape. An outer edge of each of the inductor 4 and the plurality of inductors 5 has a quadrangle shape in a plan view from the thickness direction D1 of the mounting substrate 110.

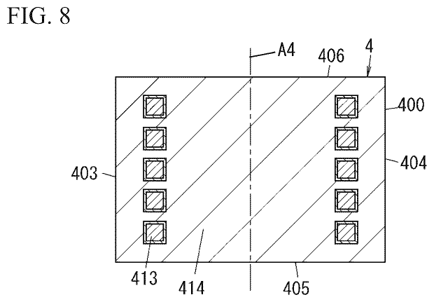

As illustrated in FIGS. 7 and 8, the inductor 4 includes, for example, a rectangular parallelepiped-shaped element body 400, a first outer electrode 411, a second outer electrode 412, and a winding portion (coil conductor portion) 413. A shape of the winding portion 413 is, for example, a helical shape. The winding portion 413 has conductivity. The element body 400 has electrical insulating properties. The first outer electrode 411 and the second outer electrode 412 are disposed at a first end and a second end of the element body 400, respectively, in a longitudinal direction. A conductive material of the first outer electrode 411 and the second outer electrode 412 is, for example, Cu, Ag, or the like. The winding portion 413 is disposed in the element body 400. The winding portion 413 is connected between the first outer electrode 411 and the second outer electrode 412. More specifically, the winding portion 413 has a first end and a second end, the first end of the winding portion 413 is connected to the first outer electrode 411, and the second end of the winding portion 413 is connected to the second outer electrode 412. A material of the winding portion 413 includes, for example, the same conductive material as the first outer electrode 411 and the second outer electrode 412, but the present disclosure is not limited thereto. The winding axis A4 of the winding portion 413 is a central shaft of the winding portion 413.

A surface of the element body 400 includes a top surface 401 on a side opposite to the side of the mounting substrate 110, a bottom surface 402 on the side of the mounting substrate 110, a first side surface 403 and a second side surface 404 connecting the top surface 401 and the bottom surface 402 and provided along a lateral direction of the element body 400, and a third side surface 405 and a fourth side surface 406 connecting the top surface 401 and the bottom surface 402 and provided along the longitudinal direction of the element body 400. The first outer electrode 411 may be provided straddling the bottom surface 402, the first side surface 403, the third side surface 405, the fourth side surface 406, and the top surface 401 of the element body 400, but may be at least provided while straddling the bottom surface 402 and the first side surface 403 of the element body 400. The second outer electrode 412 may be provided straddling the bottom surface 402, the second side surface 404, the third side surface 405, the fourth side surface 406, and the top surface 401 of the element body 400, but may be at least provided while straddling the bottom surface 402 and the second side surface 404 of the element body 400.

The inductor 4 is mounted on the first main surface 111 of the mounting substrate 110 by bonding the first outer electrode 411 and the second outer electrode 412 to the first main surface 111 of the mounting substrate 110 by a first bonding portion and a second bonding portion corresponding to the first outer electrode 411 and the second outer electrode 412 in a one-to-one manner. A material of each of the first bonding portion and the second bonding portion is, for example, solder.

The inductor 4 is disposed on the first main surface 111 of the mounting substrate 110 such that the winding axis A4 of the winding portion 413 is along the first main surface 111 of the mounting substrate 110. In other words, the inductor 4 is disposed such that the winding axis A4 of the winding portion 413 of the inductor 4 is orthogonal to the thickness direction D1 of the mounting substrate 110. The fact that “the winding axis A4 of the winding portion 413 of the inductor 4 is orthogonal to the thickness direction D1 of the mounting substrate 110” means that an angle formed by the winding axis A4 and the thickness direction D1 of the mounting substrate 110 may be within a range of, for example, 80° or greater and 100° or less, without necessarily being limited to a case where the winding axis A4 and the thickness direction D1 of the mounting substrate 110 are strictly orthogonal. The winding axis A4 of the inductor 4 is along one direction orthogonal to the thickness direction D1 of the mounting substrate 110. The winding axis A4 of the winding portion 413 of the inductor 4 is parallel to the lateral direction of the element body 400 of the inductor 4 in a plan view from the thickness direction D1 of the mounting substrate 110, and intersects the third side surface 405 and the fourth side surface 406 of the element body 400. The winding axis A4 of the winding portion 413 of the inductor 4 is parallel to the lateral direction of the element body 400, but is not limited to a case where winding axis A4 of the winding portion 413 of the inductor 4 is strictly parallel to the lateral direction of the element body 400, and the angle formed by the winding axis A4 and the lateral direction of the element body 400 may be 10° or less.

The plurality of inductors 5 may have the same structure as the inductor 4 or may have a structure different from the inductor 4. The fact that the inductor 5 has the same structure as the inductor 4 means that the winding axis of the winding portion of the inductor 5 is the same as the winding axis A4 of the winding portion 413 of the inductor 4, that is, is along one direction orthogonal to the thickness direction D1 of the mounting substrate 110. The fact that the inductor 5 has a structure different from the inductor 4 means that, for example, the winding axis of the winding portion of the inductor 5 is parallel to the thickness direction D1 of the mounting substrate 110 or the winding axis of the winding portion of the inductor 5 is parallel to the longitudinal direction of the element body of the inductor 5. The structure of the inductor 4 is selected according to, for example, a Q (quality factor) value of the inductor 4, an inductance of the inductor 4, a chip size of the inductor 4, and the like. The structure of each of the plurality of inductors 5 is selected according to the Q value of the inductor 5, the inductance of the inductor 5, the chip size of the inductor 5, and the like.

(1.2.3) External Connection Terminal

As illustrated in FIG. 2, the plurality of external connection terminals TO are disposed on the second main surface 112 of the mounting substrate 110. The fact that “the external connection terminals TO are disposed on the second main surface 112 of the mounting substrate 110” means that the external connection terminals TO are mechanically connected to the second main surface 112 of the mounting substrate 110 and the external connection terminals TO are electrically connected to the (appropriate conductor portion of) mounting substrate 110. A material of the plurality of external connection terminals TO is, for example, metal (for example, copper, copper alloy, and the like). Each of the plurality of external connection terminals TO is a columnar electrode. The columnar electrode is, for example, a cylindrical electrode. The plurality of external connection terminals TO are bonded to the conductor portion of the mounting substrate 110, for example, by using solder, but the present disclosure is not limited thereto, and for example, the plurality of external connection terminals TO may be bonded to the conductor portion of the mounting substrate 110 by using a conductive adhesive (for example, conductive paste), or may be directly bonded to the conductor portion of the mounting substrate 110. Each of the plurality of external connection terminals TO has a circular shape in a plan view from the thickness direction D1 of the mounting substrate 110.

The plurality of external connection terminals TO include the antenna terminal T1, the signal output terminal T2 (see FIG. 9), and the plurality of external ground terminals T3. The plurality of external ground terminals T3 are electrically connected to at least one of the first ground conductor portion 115 and the second ground conductor portion 116 of the mounting substrate 110.

(1.2.4) First Resin Layer

As illustrated in FIG. 2, the first resin layer 120 is disposed on the first main surface 111 of the mounting substrate 110. The first resin layer 120 covers the plurality of electronic components mounted on the first main surface 111 of the mounting substrate 110. As described above, the plurality of electronic components include the first electronic component E1, the second electronic component E2, the third electronic component E3, the fourth electronic component E4, the fifth electronic component E5, and the plurality of inductors L0 to L17. The first resin layer 120 includes a resin (for example, epoxy resin). The first resin layer 120 may contain a filler in addition to the resin.

(1.2.5) Second Resin Layer

As illustrated in FIG. 2, the second resin layer 150 is disposed on the second main surface 112 of the mounting substrate 110. The second resin layer 150 covers an outer peripheral surface of one electronic component (IC chip 8) mounted on the second main surface 112 of the mounting substrate 110 and an outer peripheral surface of each of the plurality of external connection terminals TO. The outer peripheral surface of the electronic component includes four side surfaces of the electronic component. The second resin layer 150 does not cover the main surface of the electronic component on a side opposite to the side of the mounting substrate 110. As described above, the electronic component includes the first switch 7, the second switch 9, and the IC chip 8 having the plurality of low noise amplifiers 80 to 89. The second resin layer 150 includes a resin (for example, epoxy resin). The second resin layer 150 may contain a filler in addition to the resin. A material of the second resin layer 150 may be the same as or different from the material of the first resin layer 120.

(1.2.6) Metal Electrode Layer

As illustrated in FIG. 2, the metal electrode layer 130 covers the first resin layer 120. The metal electrode layer 130 is connected to the external ground terminal T3 of the mounting substrate 110. The metal electrode layer 130 has conductivity. In the high frequency module 500, the metal electrode layer 130 is a shield layer provided for the purpose of electromagnetic shield inside and outside the high frequency module 500. The metal electrode layer 130 has a multilayer structure in which a plurality of metal layers are laminated, but the present disclosure is not limited thereto, and the metal electrode layer 130 may be formed of one metal layer. The metal layer includes one or more metals. When the metal electrode layer 130 has a multilayer structure in which the plurality of metal layers are laminated, the metal electrode layer 130 includes, for example, a first stainless steel layer on the first resin layer 120, a Cu layer on the first stainless steel layer, and a second stainless steel layer on the Cu layer. A material of each of the first stainless steel layer and the second stainless steel layer is an alloy including Fe, Ni, and Cr. In addition, the metal electrode layer 130 is, for example, a Cu layer when it is formed of one metal layer. The metal electrode layer 130 covers a main surface 121 of the first resin layer 120 on a side opposite to the side of the mounting substrate 110, an outer peripheral surface 123 of the first resin layer 120, an outer peripheral surface 113 of the mounting substrate 110, and an outer peripheral surface 153 of the second resin layer 150. The main surface 151 of the second resin layer 150 on the side opposite to the side of the mounting substrate 110 is exposed without necessarily being covered with the metal electrode layer 130. The metal electrode layer 130 is electrically connected to the first ground conductor portion 115, the second ground conductor portion 116, and the plurality of external ground terminals T3 of the mounting substrate 110. Accordingly, the high frequency module 500 can set a potential of the metal electrode layer 130 to be substantially the same potential as a potential of the first ground conductor portion 115 and the second ground conductor portion 116 of the mounting substrate 110.

(1.3) Layout of High Frequency Module

As illustrated in FIG. 1, in the high frequency module 500, the first electronic component E1 is adjacent to the inductor 4 in a plan view from the thickness direction D1 of the mounting substrate 110. The fact that “the first electronic component E1 is adjacent to the inductor 4” means that there is no other electronic component disposed on the first main surface 111 of the mounting substrate 110 between the first electronic component E1 and the inductor 4 in a plan view from the thickness direction D1 of the mounting substrate 110, and the first electronic component E1 is adjacent to the inductor 4.

In the high frequency module 500, the antenna end resonator 14A of the first electronic component E1 is adjacent to the inductor 4 in a plan view from the thickness direction D1 of the mounting substrate 110. The fact that “the antenna end resonator 14A is adjacent to the inductor 4” means that the first functional electrode 11 is adjacent to the inductor 4 without necessarily any of the plurality of third functional electrodes 31 (see FIG. 5), which correspond to the plurality of second acoustic wave resonators 24 of the second filter 2 (filter 66) of the first electronic component E1 in a one-to-one manner, the plurality of functional electrodes, which correspond to the plurality of acoustic wave resonators of the filter 67 in a one-to-one manner, and other electronic component disposed on the first main surface 111 of the mounting substrate 110 between the inductor 4 and the first functional electrode 11 forming a part of the antenna end resonator 14A in a plan view from the thickness direction D1 of the mounting substrate 110. As described above, the inductor 4 does not overlap the antenna end resonator 14A when in a side view from the direction of the winding axis A4. In addition, in the inductor 4, the antenna end resonator 14A does not overlap the inner part 414 (see FIG. 8) of the winding portion 413 of the inductor 4 in a side view from a side opposite to a side of the first electronic component E1. The inner part 414 of the winding portion 413 is a part of the element body 400 that is located inward of the winding portion 413. The shortest distance between the winding axis A4 of the inductor 4 and the first functional electrode 11 is, for example, 200 μm or greater in a plan view from the thickness direction D1 of the mounting substrate 110.

In the high frequency module 500, the winding axis A4 of the inductor 4 does not overlap the first functional electrode 11 of the antenna end resonator 14A in a plan view from the thickness direction D1 of the mounting substrate 110. Further, in the high frequency module 500, the inductor 4 and the first functional electrode 11 of the antenna end resonator 14A are arranged in a direction orthogonal to the winding axis A4 of the winding portion 413 of the inductor 4 in a plan view from the thickness direction D1 of the mounting substrate 110. The inductor 4 is an inductor having the shortest distance from the first functional electrode 11 among the plurality of inductors L0 to L17. In the high frequency module 500, the winding axis of the winding portion of each of three inductors 5, which are adjacent to the first electronic component E1, does not overlap the first functional electrode 11 of the antenna end resonator 14A in a plan view from the thickness direction D1 of the mounting substrate 110.

Moreover, in the high frequency module 500, the IC chip 8 disposed on the second main surface 112 of the mounting substrate 110 overlaps a part of each of the first electronic component E1, the second electronic component E2, the third electronic component E3, the fourth electronic component E4, and the fifth electronic component E5, in a plan view from the thickness direction D1 of the mounting substrate 110.

As illustrated in FIG. 1, in the high frequency module 500, the first ground conductor portion 115 at least partially overlaps the first electronic component E1 in a plan view from the thickness direction D1 of the mounting substrate 110. At least a part of the second ground conductor portion 116 overlaps the second electronic component E2 in a plan view from the thickness direction D1 of the mounting substrate 110. A ratio of an area of a part overlapping the second ground conductor portion 116 to an area of the second electronic component E2 is greater than a ratio of an area of a part overlapping the first ground conductor portion 115 to an area of the first electronic component E1, in a plan view from the thickness direction D1 of the mounting substrate 110. In addition, in the high frequency module 500, the area of the part of the second ground conductor portion 116 overlapping the second electronic component E2 is larger than the area of the part of the first ground conductor portion 115 overlapping the first electronic component E1, in a plan view from the thickness direction D1 of the mounting substrate 110.

(2) Effect

According to the first embodiment, the high frequency module 500 includes the mounting substrate 110, the antenna terminal T1, the filter 1, and the inductor 4. The mounting substrate 110 has the first main surface 111 and the second main surface 112 that are opposite to each other. The antenna terminal T1 is disposed on the mounting substrate 110. The filter 1 is connected to the antenna terminal T1. The inductor 4 is disposed on the first main surface 111 of the mounting substrate 110. The inductor 4 includes the winding portion 413. The filter 1 has the plurality of acoustic wave resonators 14. The plurality of acoustic wave resonators 14 include the plurality of series arm resonators S1 to S4 provided on the signal path Ru1 connected to the antenna terminal T1, and the plurality of parallel arm resonators P1 to P4 connected between the signal path Ru1 and the ground. When at least one of the series arm resonator S1, which is closest to the antenna terminal T1 among the plurality of series arm resonators S1 to S4, and the parallel arm resonator P1, which is closest to the antenna terminal T1 among the plurality of parallel arm resonators P1 to P4, is defined as the antenna end resonator 14A, the filter 1 includes the first substrate (substrate 10), the first functional electrode 11 provided on the first substrate and forming a part of the antenna end resonator 14A, the second substrate (substrate 20) separate from the first substrate, and the second functional electrode 21 provided on the second substrate and forming a part of at least one acoustic wave resonator 14 other than the antenna end resonator 14A among the plurality of acoustic wave resonators 14. The first electronic component E1 including the first substrate and the first functional electrode 11 is disposed on the first main surface 111 of the mounting substrate 110. The second electronic component E2 including the second substrate and the second functional electrode 21 is disposed on the first main surface 111 of the mounting substrate 110. A distance between the antenna terminal T1 and the first electronic component E1 is shorter than a distance between the antenna terminal T1 and the second electronic component E2. The inductor 4 is adjacent to the first electronic component E1 in a plan view from a thickness direction D1 of the mounting substrate 110. The inductor 4 does not overlap the antenna end resonator 14A when in a side view from a direction of the winding axis A4 of the winding portion 413.

According to the first embodiment, the high frequency module 500 can reduce the deterioration in characteristics of the filter 1. More specifically, in the high frequency module 500, since the inductor 4 does not overlap the antenna end resonator 14A in a side view from the direction of the winding axis A4 of the winding portion 413 of the inductor 4, the antenna end resonator 14A is not easily affected by the magnetic field of the inductor 4, and it is possible to suppress deterioration in characteristics of the filter 1 due to the influence of the magnetic field of the inductor 4.

Moreover, since in the high frequency module 500, the parallel arm resonator P1 is defined as the antenna end resonator 14A among the plurality of series arm resonators S1 to S4 and the plurality of parallel arm resonators P1 to P4 of the filter 1, it is possible to suppress deterioration in attenuation characteristics of the filter 1 due to the influence of the inductor 4.

In the high frequency module 500, when the series arm resonator S1 is defined as the antenna end resonator 14A among the plurality of series arm resonators S1 to S4 and the plurality of parallel arm resonators P1 to P4 of the filter 1, it is possible to suppress deterioration in characteristics of the pass band of the filter 1 due to the influence of the inductor 4. In the high frequency module 500, when each of the series arm resonator S1 and the parallel arm resonator P1 is defined as the antenna end resonator 14A among the plurality of series arm resonators S1 to S4 and the plurality of parallel arm resonators P1 to P4 of the filter 1, it is possible to suppress deterioration in characteristics of the pass band of the filter 1 and the attenuation characteristics due to the influence of the inductor 4.

Moreover, as for the first filter 1 (filter 63) and the second filter 2 (filter 66) used for simultaneous communication, the high frequency module 500 includes the antenna end resonator 14A of the first filter 1 and the antenna end resonator from among a plurality of second acoustic wave resonators 24 of the second filter 2 in the first electronic component E1, it is possible to reduce loss and parasitic capacitance generated in wiring between the antenna end resonator of the second filter 2 and the switch 7. Therefore, the high frequency module 500 can suppress the decrease in impedance of the first filter 1 in the frequency band of the second communication band. For example, in a smith chart, the impedance of the first filter 1 can be made to be near the open (infinite) in the frequency band of the second communication band.

Accordingly, in the high frequency module 500, even when the antenna end resonator 14A of the first filter 1 is connected to the antenna end resonator of the second filter 2, the impedance of the first filter 1 hardly changes during simultaneous communication. Therefore, the high frequency module 500 can suppress the deterioration in characteristics during simultaneous communication.

Moreover, the high frequency module 500 according to the first embodiment has a high degree of freedom in arranging the second electronic component E2 on the first main surface 111 of the mounting substrate 110, and for example, the second electronic component E2 can be disposed in an area having high heat dissipating properties in the mounting substrate 110. Therefore, in the high frequency module 500 according to the first embodiment, for example, the second electronic component E2 is easily disposed such that the ratio of the area of a part overlapping the second ground conductor portion 116 to the area of the second electronic component E2 is greater than the ratio of the area of the part overlapping the first ground conductor portion 115 to the area of the first electronic component E1, in a plan view from the thickness direction D1 of the mounting substrate 110. In addition, in the high frequency module 500, for example, the second electronic component E2 is easily disposed such that the area of the part of the second ground conductor portion 116 overlapping the second electronic component E2 is larger than the area of the part of the first ground conductor portion 115 overlapping the first electronic component E1, in a plan view from the thickness direction D1 of the mounting substrate 110. Therefore, the high frequency module 500 can improve heat dissipating properties and electric power handling capability, and can suppress characteristics of fluctuation due to a temperature increase.

(3) Communication Device

According to the first embodiment, the communication device 600 includes, for example, the signal processing circuit 601 and the high frequency module 500, as illustrated in FIG. 9. The signal processing circuit 601 is connected to the high frequency module 500.

The communication device 600 further includes an antenna 610. The communication device 600 further includes a circuit substrate on which the high frequency module 500 is mounted. The circuit substrate is, for example, a printed wiring board. The circuit substrate has a ground electrode to which a ground potential is applied.

The signal processing circuit 601 includes, for example, an RF signal processing circuit 602 and a baseband signal processing circuit 603. The RF signal processing circuit 602 is, for example, a radio frequency integrated circuit (RFIC), and performs signal processing on a high frequency signal. The RF signal processing circuit 602 performs signal processing, such as upconversion, on the high frequency signal (transmission signal) output from the baseband signal processing circuit 603, and outputs the high frequency signal on which the signal processing is performed. In addition, the RF signal processing circuit 602 performs signal processing, such as downconversion, on the high frequency signal (reception signal) output from the high frequency module 500, and outputs the high frequency signal on which the signal processing is performed to the baseband signal processing circuit 603. The baseband signal processing circuit 603 is, for example, a baseband integrated circuit (BBIC). The baseband signal processing circuit 603 generates an I phase signal and a Q phase signal from the baseband signal. The baseband signal is, for example, an audio signal, an image signal, and the like input from the outside. The baseband signal processing circuit 603 performs IQ modulation processing by combining the I phase signal and the Q phase signal, and outputs the transmission signal. In this case, the transmission signal is generated as a modulation signal (IQ signal) by amplitude modulation of a carrier wave signal of a predetermined frequency in a period longer than a period of the carrier wave signal. The reception signal processed by the baseband signal processing circuit 603 is used, for example, as an image signal for image display or as an audio signal for a call of the user of the communication device 600. The high frequency module 500 transmits the high frequency signal (reception signal and transmission signal) between the antenna 610 and the RF signal processing circuit 602 of the signal processing circuit 601.

Since the communication device 600 according to the first embodiment includes the high frequency module 500 and the signal processing circuit 601, it is possible to reduce the deterioration of the filter 1.

(4) Another Example of Antenna End Resonator of Filter

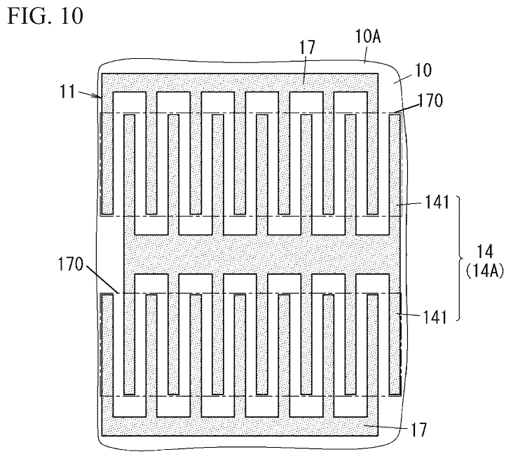

The antenna end resonator 14A may be configured with, for example, two divided resonators 141 as illustrated in FIG. 10. In this case, the two divided resonators 141 are resonators obtained by dividing the antenna end resonator 14A, and are connected in series without necessarily interposing another acoustic wave resonator 14 therebetween and without necessarily interposing a connection node with a path including the other acoustic wave resonator 14.

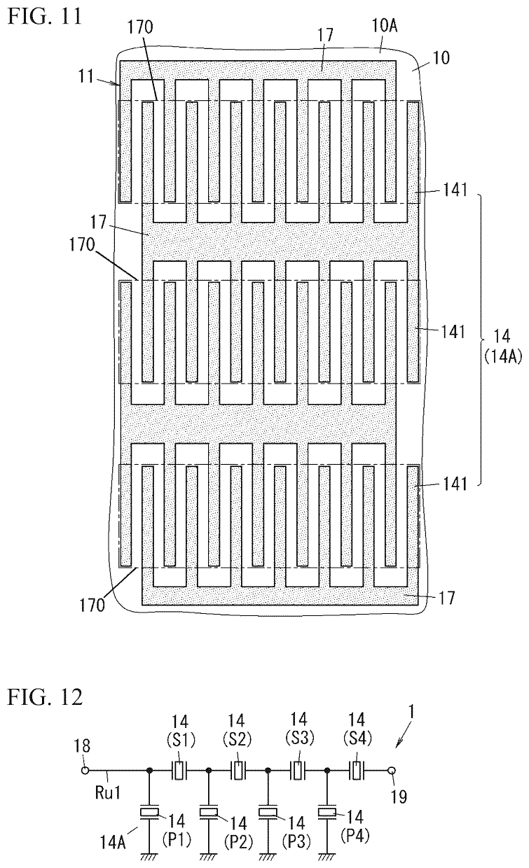

Moreover, the antenna end resonator 14A may be configured with, for example, three divided resonators 141 as illustrated in FIG. 11. In this case, the three divided resonators 141 are resonators obtained by dividing the antenna end resonator 14A, and are connected in series without necessarily interposing another acoustic wave resonator 14 therebetween and without necessarily interposing a connection node with a path including the other acoustic wave resonator 14.

(5) Another Circuit Example of Filter

The filter 1 is not limited to the circuit configuration of FIG. 3A, but may have, for example, a circuit configuration illustrated in FIG. 12. In the filter 1 illustrated in FIG. 12, the parallel arm resonator P1 is connected between a part of the signal path Ru1 between the input/output terminal 18 and the series arm resonator S1 and the ground, and the parallel arm resonator P1 and the series arm resonator S1 are connected to the input/output terminal 18 with no other acoustic wave resonator 14 interposed therebetween. In the filter 1 illustrated in FIG. 12, for example, the parallel arm resonator P1 is used as the antenna end resonator 14A, but the present disclosure is not limited thereto, and the series arm resonator S1 may be used as the antenna end resonator 14A or each of the series arm resonator S1 and the parallel arm resonator P1 may be used as the antenna end resonator 14A.

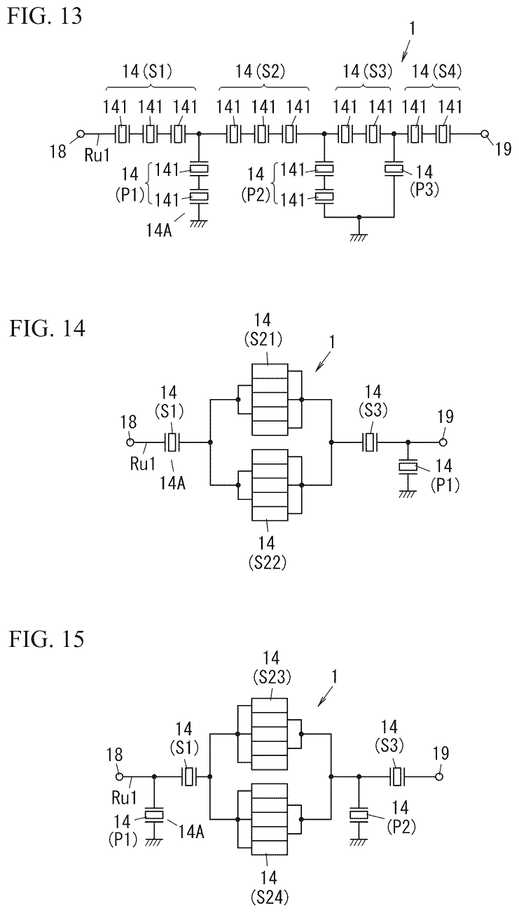

The filter 1 is not limited to the circuit configuration of FIG. 3A, but may have, for example, a circuit configuration as illustrated in FIG. 13. In the filter 1 illustrated in FIG. 13, each of the series arm resonator S1 and the series arm resonator S2 is configured with three divided resonators 141, and each of the series arm resonator S3 and the series arm resonator S4 is configured with two divided resonators 141. In addition, in the filter 1 illustrated in FIG. 13, each of the parallel arm resonator P1 and the parallel arm resonator P2 is configured with two divided resonators 141. In the filter 1 illustrated in FIG. 13, for example, the parallel arm resonator P1 is used as the antenna end resonator 14A, but the present disclosure is not limited thereto, and the series arm resonator S1 may be used as the antenna end resonator 14A or each of the series arm resonator S1 and the parallel arm resonator P1 may be used as the antenna end resonator 14A. The circuit configuration of FIG. 13 is an example of the circuit configuration of the filter 1 employed when the first communication band is Band 30 of the 3GPP LTE standard.

The filter 1 is not limited to the circuit configuration of FIG. 3A, but may have, for example, a circuit configuration as illustrated in FIG. 14. In the filter 1 illustrated in FIG. 14, a parallel circuit of a vertically coupled resonator S21 and a vertically coupled resonator S22 is provided between the series arm resonator S1 and the series arm resonator S3. Each of the vertically coupled resonator S21 and the vertically coupled resonator S22 has five IDT electrodes 27 (see FIG. 6). In the filter 1 illustrated in FIG. 14, for example, the series arm resonator S1 is defined as the antenna end resonator 14A. The circuit configuration of FIG. 14 is an example of the circuit configuration of the filter 1 employed when the first communication band is Band 66 of the 3GPP LTE standard.

The filter 1 is not limited to the circuit configuration of FIG. 3A, but may have, for example, a circuit configuration as illustrated in FIG. 15. In the filter 1 illustrated in FIG. 15, the parallel arm resonator P1 is connected between a part of the signal path Ru1 between the input/output terminal 18 and the series arm resonator S1 and the ground, and the parallel arm resonator P1 the series arm resonator S1 are connected to the input/output terminal 18 with no other acoustic wave resonator 14 interposed therebetween. In the filter 1 illustrated in FIG. 15, for example, the parallel arm resonator P1 is used as the antenna end resonator 14A, but the present disclosure is not limited thereto, and the series arm resonator S1 may be used as the antenna end resonator 14A or each of the series arm resonator S1 and the parallel arm resonator P1 may be used as the antenna end resonator 14A. In addition, in the filter 1 illustrated in FIG. 15, a parallel circuit of a vertically coupled resonator S23 and a vertically coupled resonator S24 is provided between the series arm resonator S1 and the series arm resonator S3. Each of the vertically coupled resonator S23 and the vertically coupled resonator S24 has five IDT electrodes 27 (see FIG. 6). The circuit configuration of FIG. 15 is an example of the circuit configuration of the filter 1 employed when the first communication band is Band 3 of the 3GPP LTE standard.

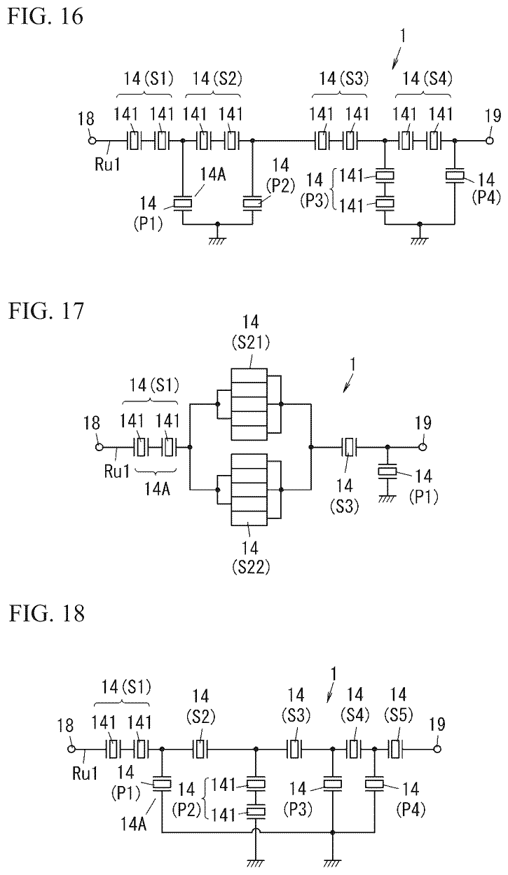

The filter 1 is not limited to the circuit configuration of FIG. 3A, but may have, for example, a circuit configuration as illustrated in FIG. 16. In the filter 1 illustrated in FIG. 16, each of the series arm resonator S1, the series arm resonator S2, the series arm resonator S3, and the series arm resonator S4 is configured with two divided resonators 141, and the parallel arm resonator P3 is configured with two divided resonators 141. In the filter 1 illustrated in FIG. 16, for example, the parallel arm resonator P1 is used as the antenna end resonator 14A, but the present disclosure is not limited thereto, and the series arm resonator S1 may be used as the antenna end resonator 14A or each of the series arm resonator S1 and the parallel arm resonator P1 may be used as the antenna end resonator 14A. The circuit configuration of FIG. 16 is an example of the circuit configuration of the filter 1 employed when the first communication band is Band 7 of the 3GPP LTE standard.

The filter 1 is not limited to the circuit configuration of FIG. 3A, but may have, for example, a circuit configuration as illustrated in FIG. 17. In the filter 1 illustrated in FIG. 17, the series arm resonator S1 is configured with two divided resonators 141. In addition, in the filter 1 illustrated in FIG. 17, a parallel circuit of a vertically coupled resonator S21 and a vertically coupled resonator S22 is provided between the series arm resonator S1 and the series arm resonator S3. Each of the vertically coupled resonator S21 and the vertically coupled resonator S22 has five IDT electrodes 27 (see FIG. 6). In the filter 1 illustrated in FIG. 17, for example, the series arm resonator S1 is defined as the antenna end resonator 14A. The circuit configuration of FIG. 17 is an example of the circuit configuration of the filter 1 employed when the first communication band is Band 1 of the 3GPP LTE standard.

The filter 1 is not limited to the circuit configuration of FIG. 3A, but may have, for example, a circuit configuration as illustrated in FIG. 18. In the filter 1 illustrated in FIG. 18, the series arm resonator S1 is configured with two divided resonators 141, and the parallel arm resonator P2 is configured with two divided resonators 141. In addition, the filter 1 illustrated in FIG. 18 further includes an acoustic wave resonator 14 (series arm resonator S5) connected between the series arm resonator S4 and the input/output terminal 19. In the filter 1 illustrated in FIG. 18, for example, the parallel arm resonator P1 is used as the antenna end resonator 14A, but the present disclosure is not limited thereto, and the series arm resonator S1 may be used as the antenna end resonator 14A or each of the series arm resonator S1 and the parallel arm resonator P1 may be used as the antenna end resonator 14A. The circuit configuration of FIG. 18 is an example of the circuit configuration of the filter 1 employed when the first communication band is Band 40 of the 3GPP LTE standard.

(6) Another Example of First Electronic Component and Second Electronic Component

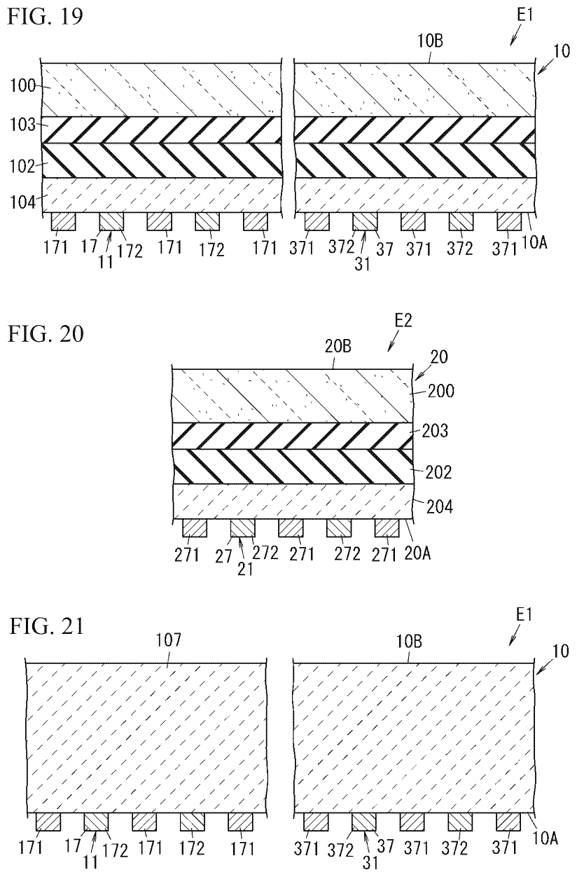

As illustrated in FIG. 19, the substrate 10 of the first electronic component E1 may include, for example, a support substrate 100 (hereinafter also referred to as a first support substrate 100) and a high velocity film 103 (hereinafter also referred to as a first high velocity film 103) interposed between the first support substrate 100 and the first low velocity film 102, instead of the first high velocity member 101. The first high velocity film 103 is a film in which the velocity of the bulk wave propagating through the first high velocity film 103 is faster than the velocity of the acoustic wave propagating through the first piezoelectric layer 104. The first high velocity film 103 forms a first high velocity member. Further, as illustrated in FIG. 20, the substrate 20 of the second electronic component E2 may include, for example, a support substrate 200 (hereinafter also referred to as a second support substrate 200) and a high velocity film 203 (hereinafter also referred to as a second high velocity film 203) interposed between the second support substrate 200 and the second low velocity film 202, instead of the second high velocity member 201. The second high velocity film 203 is a film in which the velocity of the bulk wave propagating through the second high velocity film 203 is faster than the velocity of the acoustic wave propagating through the second piezoelectric layer 204. The second high velocity film 203 forms the second high velocity member. A material of the first high velocity film 103 and the second high velocity film 203 is, for example, silicon nitride, but is not limited to silicon nitride, and may be at least one type of material selected from a group made up of diamond-like carbon, aluminum nitride, silicon carbide, silicon nitride, silicon oxynitride, silicon, sapphire, lithium tantalate, lithium niobate, crystal, zirconia, cordierite, mullite, steatite, forsterite, magnesia, and diamond.

Moreover, the first electronic component E1 may include, for example, an adhesion layer (hereinafter also referred to as a first adhesion layer) interposed between the first low velocity film 102 and the first piezoelectric layer 104. The first adhesion layer is formed of, for example, a resin (epoxy resin, polyimide resin). Further, the first electronic component E1 may include a dielectric film (first dielectric film) between the first low velocity film 102 and the first piezoelectric layer 104, on the first piezoelectric layer 104, or under the first low velocity film 102. Further, the second electronic component E2 may include, for example, an adhesion layer (hereinafter also referred to as a second adhesion layer) interposed between the second low velocity film 202 and the second piezoelectric layer 204. The second adhesion layer is formed of, for example, a resin (epoxy resin, polyimide resin). In addition, the second electronic component E2 includes a dielectric film between the second low velocity film 202 and the second piezoelectric layer 204, on the second piezoelectric layer 204, or under the second low velocity film 202. In addition, the first electronic component E1 may further include a protective film (hereinafter also referred to as a first protective film) provided on the first piezoelectric layer 104 to cover the plurality of first functional electrodes 11 and third functional electrodes 31. A material of the first protective film is, for example, silicon oxide. Further, the second electronic component E2 may further include a protective film (hereinafter also referred to as a second protective film) provided on the second piezoelectric layer 204 to cover the plurality of second functional electrodes 21. A material of the second protective film is, for example, silicon oxide.

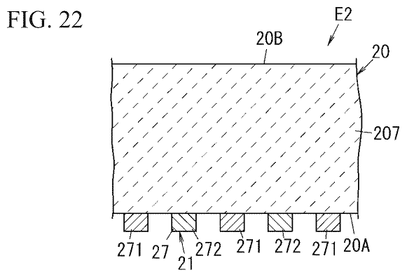

Moreover, in the first electronic component E1, the antenna end resonator 14A and the second acoustic wave resonator 24 may be, for example, surface acoustic wave (SAW) resonator as illustrated in FIG. 21. In this case, as illustrated in FIG. 21, in the first electronic component E1, the substrate 10 may include a piezoelectric substrate 107 (hereinafter also referred to as a first piezoelectric substrate 107) instead of the first high velocity member 101 and the first low velocity film 102. The first piezoelectric substrate 107 is, for example, a lithium tantalate substrate or a lithium niobate substrate. In addition, in the second electronic component E2, the first acoustic wave resonator 14 may be, for example, a SAW resonator as illustrated in FIG. 22. In this case, as illustrated in FIG. 22, in the second electronic component E2, the substrate 20 may include a piezoelectric substrate 207 (hereinafter also referred to as a second piezoelectric substrate 207) instead of the second high velocity member 201 and the second low velocity film 202. The second piezoelectric substrate 207 is, for example, a lithium tantalate substrate or a lithium niobate substrate. In the high frequency module 500, for example, when the substrate 10 of the first electronic component E1 is the piezoelectric substrate 107, and the substrate 20 of the second electronic component E2 includes the second high velocity member 201 and the second low velocity film 202, sensitivity of the antenna end resonator 14A to the magnetic field of the inductor 4 can be reduced.

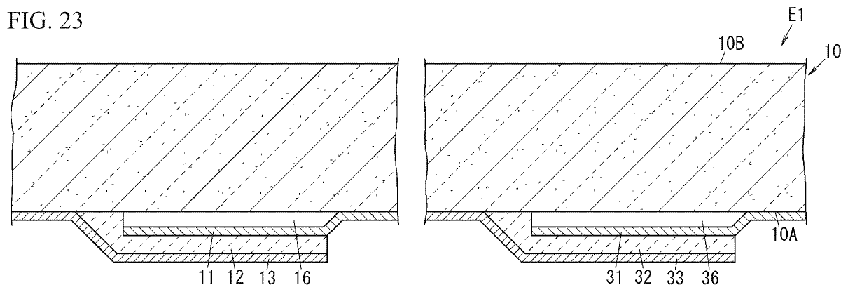

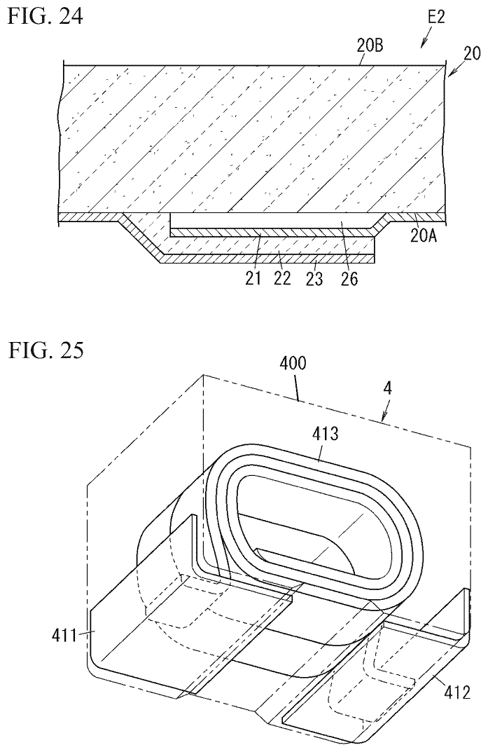

Moreover, in the first electronic component E1, the antenna end resonator 14A may be, for example, a bulk acoustic wave (BAW) resonator as illustrated in FIG. 23. In this case, in the first electronic component E1, the first substrate (substrate 10) is a silicon substrate or a spinel substrate, and the BAW resonator constituting the antenna end resonator 14A includes a lower electrode (hereinafter also referred to as a first lower electrode), which is the first functional electrode 11 provided on a side of the first main surface 10A of the substrate 10, a piezoelectric film 12 (hereinafter also referred to as a first piezoelectric film 12) provided on the first lower electrode, and an upper electrode 13 (hereinafter also referred to as a first upper electrode 13) provided on the first piezoelectric film 12. A material of the first piezoelectric film 12 is, for example, AlN, ScAlN, or PZT (lead zirconate titanate). The BAW resonator constituting the antenna end resonator 14A has a cavity 16 on a side opposite to a side of the first piezoelectric film 12 in the first functional electrode 11. The BAW resonator constituting the antenna end resonator 14A is a film bulk acoustic resonator (FBAR), but is not limited thereto, and may be a solidly mounted resonator (SMR). In addition, in the second electronic component E2, the acoustic wave resonator 14 may be, for example, a BAW resonator as illustrated in FIG. 24. In this case, in the second electronic component E2, the second substrate (substrate 20) is a silicon substrate or a spinel substrate, and the BAW resonator constituting the acoustic wave resonator 14 includes a lower electrode (hereinafter also referred to as a second lower electrode), which is the second functional electrode 21 provided on a side of the first main surface 20A of the substrate 20, a piezoelectric film 22 (hereinafter also referred to as a second piezoelectric film 22) provided on the second lower electrode, and an upper electrode 23 (hereinafter also referred to as a second upper electrode 23) provided on the second piezoelectric film 22. A material of the second piezoelectric film 22 is, for example, AlN, ScAlN, or PZT. The BAW resonator constituting the acoustic wave resonator 14 has a cavity 26 on a side opposite to a side of the second piezoelectric film 22 in the second functional electrode 21. In addition, in the first electronic component E1, the second acoustic wave resonator 24 may be, for example, a BAW resonator as illustrated in FIG. 23. In this case, in the first electronic component E1, the third substrate (substrate 10) is a silicon substrate or a spinel substrate, and the BAW resonator constituting the second acoustic wave resonator 24 includes a lower electrode (hereinafter also referred to as a third lower electrode), which is the third functional electrode 31 provided on a side of the first main surface 10A of the substrate 10, a piezoelectric film 32 (hereinafter also referred to as a third piezoelectric film) provided on the third lower electrode, and an upper electrode 33 (hereinafter also referred to as a third upper electrode 33) provided on the third piezoelectric film 32. A material of the third piezoelectric film 32 is, for example, AlN, ScAlN, or PZT. The BAW resonator constituting the second acoustic wave resonator 24 has a cavity 36 on a side opposite to a side of the third piezoelectric film 32 in the third functional electrode 31.

(7) Another Example of Inductor

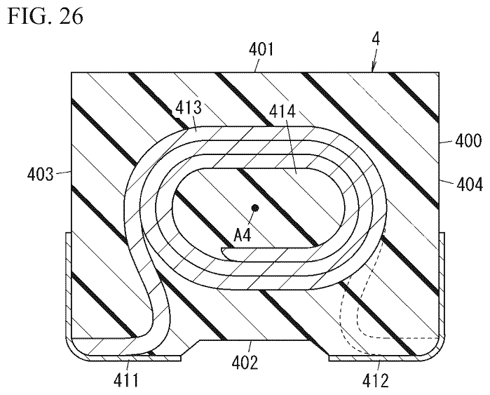

The inductor 4 may have, for example, a configuration as illustrated in FIGS. 25 and 26. In the inductor 4 illustrated in FIGS. 25 and 26, the element body 400 is a molded body made of a sealing material containing magnetic powder and a resin. The winding portion 413 is formed of a wound conductive wire. The conductive wire is, for example, a flat wire having a flat square cross section.

### Second Embodiment

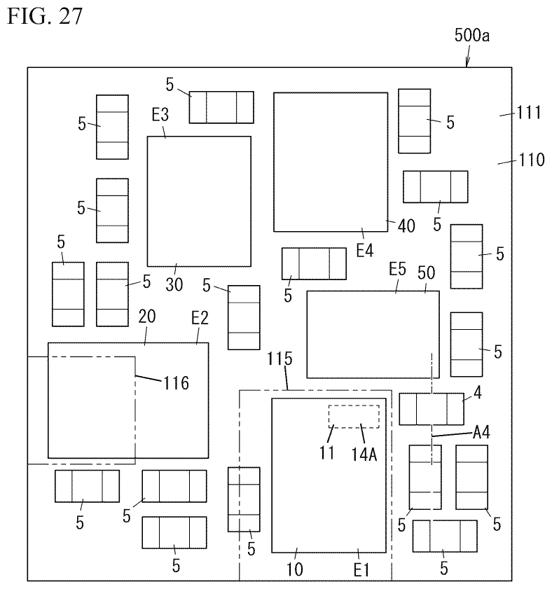

According to a second embodiment, a high frequency module 500a will be described with reference to FIG. 27. As for the high frequency module 500a according to the second embodiment, the same constituent elements as the high frequency module 500 according to the first embodiment are marked with the same reference numerals, and the description thereof is omitted.

In the high frequency module 500a, a ratio of an area of a part overlapping a first ground conductor portion 115 to an area of a first electronic component E1 is greater than a ratio of an area of a part overlapping a second ground conductor portion 116 to an area of a second electronic component E2, in a plan view from a thickness direction D1 of a mounting substrate 110. In addition, in the high frequency module 500, the area of the part of the first ground conductor portion 115 overlapping the first electronic component E1 is larger than the area of the part of the second ground conductor portion 116 overlapping the second electronic component E2, in a plan view from the thickness direction D1 of the mounting substrate 110. Therefore, the high frequency module 500a can suppress a temperature increase of the first electronic component E1 as compared with the high frequency module 500 according to the first embodiment, can improve electric power handling capability of the first electronic component E1, and can suppress characteristics of fluctuation of the first filter 1 due to the temperature increase.

### Third Embodiment

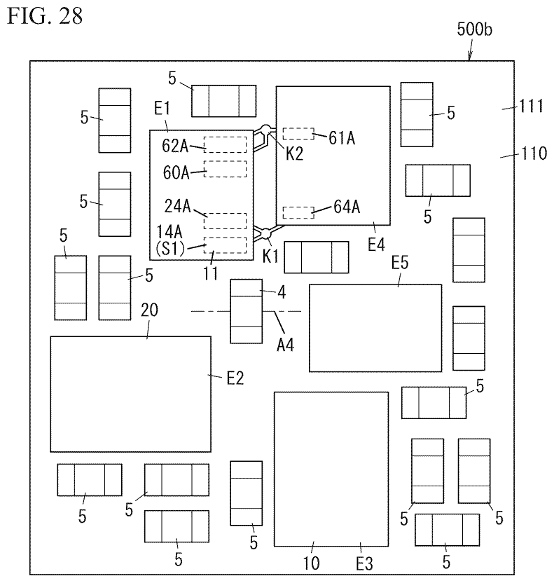

According to a third embodiment, a high frequency module 500b will be described with reference to FIG. 28. As for the high frequency module 500b according to the third embodiment, the same constituent elements as the high frequency module 500 according to the first embodiment are marked with the same reference numerals, and the description thereof is omitted.

The high frequency module 500b according to the third embodiment is different from the high frequency module 500 according to the first embodiment in that the filter 63 among the plurality of filters 60 to 69 illustrated in FIG. 9 constitutes the first filter 1, and the filter 65 constitutes the second filter 2. In the high frequency module 500b, the first electronic component E1 includes an antenna end resonator 14A (series arm resonator S1) of the first filter 1 (filter 63), a second filter 2 (filter 65), a filter 60, and an antenna end resonator 24A that is closest to an antenna terminal T1 among a plurality of acoustic wave resonators of the filter 62. Further, in the high frequency module 500b, the second electronic component E2 includes a first acoustic wave resonator 14 other than the antenna end resonator 14A among the plurality of first acoustic wave resonators 14 of the first filter 1 (filter 63), and a plurality of acoustic wave resonators other than the antenna end resonator among the plurality of acoustic wave resonators of the filter 62. In addition, in the high frequency module 500b, the third electronic component E3 includes the filter 66 and the filter 67.

In the high frequency module 500b, the antenna end resonator 14A (series arm resonator S1) of the first filter 1 (filter 63), the antenna end resonator 24A of the second filter 2 (filter 65), and an antenna end resonator 64A of the filter 64 are connected to a connection point K1 of the mounting substrate 110. In addition, in the high frequency module 500b, an antenna end resonator 62A of the filter 62, an antenna end resonator 60A of the filter 60, and an antenna end resonator 61A of the filter 61 are connected to a connection point K2 of the mounting substrate 110.

The high frequency module 500b according to the third embodiment is the same as the high frequency module 500 according to the first embodiment in that the inductor 4 does not overlap the antenna end resonator 14A in a side view from a direction of a winding axis A4 of a inductor 4, so that the antenna end resonator 14A is not easily affected by the magnetic field of the inductor 4, and it is possible to suppress deterioration in characteristics of the filter 1 due to the influence of the magnetic field of the inductor 4.

Moreover, the high frequency module 500b according to the third embodiment can shorten a distance to the connection point K1 from each of the antenna end resonator 14A (series arm resonator S1) of the first filter 1 (filter 63), the antenna end resonator 24A of the second filter 2 (filter 65), and the antenna end resonator 64A of the filter 64, can reduce stray capacitance of wiring or loss caused due to the wiring, and can suppress lowering of a noise figure (NF). Further, the high frequency module 500b can shorten a distance to the connection point K2 from each of the antenna end resonator 62A of the filter 62, the antenna end resonator 60A of the filter 60, and the antenna end resonator 61A of the filter 61, can reduce the stray capacitance of wiring or the loss caused due to the wiring, and can suppress lowering of the NF.

### Modification Example

The first to third embodiments are merely one of various embodiments of the present disclosure. The first to third embodiments may be variously modified according to a design of the present disclosure can be achieved, and different constituent elements of different embodiments may be combined as appropriate.

For example, in the high frequency modules 500, 500a, and 500b, the plurality of filters 60 to 69 may include at least the first filter 1.

Moreover, in the high frequency modules 500, 500a, and 500b, the main surface of the first electronic component E1 on the side opposite to the side of the mounting substrate 110 (second main surface 10B of the substrate 10) is in contact with the metal electrode layer 130, and the main surface of the second electronic component E2 on the side opposite to the side of the mounting substrate 110 (second main surface 20B of the substrate 20) is in contact with the metal electrode layer 130, but the present disclosure is not limited thereto. For example, the high frequency modules 500, 500a, and 500b may have a structure in which one of the main surface of the first electronic component E1 on the side opposite to the side of the mounting substrate 110 and the main surface of the second electronic component E2 on the side opposite to the side of the mounting substrate 110 is in contact with the metal electrode layer 130, or may have a structure in which both the main surface of the first electronic component E1 on the side opposite to the side of the mounting substrate 110 and the main surface of the second electronic component E2 on the side opposite to the side of the mounting substrate 110 are not in contact with the metal electrode layer 130. Moreover, the high frequency module 500 may include, instead of the IC chip 8, a first IC chip including a first switch 7, a second IC chip separate from the first IC chip and including a plurality of low noise amplifiers 80 to 89, and a third IC chip separate from the first IC chip and the second IC chip and including a second switch 9. In this case, in the high frequency module 500, at least one of the first IC chip, the second IC chip, and the third IC chip may be disposed on the first main surface 111 of the mounting substrate 110.

The communication device 600 according to the first embodiment may include the high frequency module 500a or the high frequency module 500b instead of the high frequency module 500.

Moreover, the high frequency modules 500, 500a, and 500b are not limited to reception modules including reception filters (filters 60 to 69) and the low noise amplifiers 80 to 89, and for example, may be transmission modules including a transmission filter and a power amplifier, and may be a transceiver modules including a transmission filter, a power amplifier, a reception filter, and a low noise amplifier. When the high frequency modules 500, 500a, and 500b are transmission modules, the first filter 1 is a transmission filter. When the high frequency modules 500, 500a, and 500b are transceiver modules, the first filter 1 may be a reception filter or a transmission filter.

Moreover, the high frequency modules 500, 500a, and 500b may have a configuration in which the plurality of external connection terminals TO are ball bumps and the second resin layer 150 is not provided. In this case, the high frequency modules 500, 500a, and 500b may include an underfill portion provided in a gap between the switch 7 mounted on the second main surface 112 of the mounting substrate 110 and the second main surface 112 of the mounting substrate 110. A material of the ball bump constituting each of the plurality of external connection terminals TO is, for example, gold, copper, solder, and the like. The plurality of external connection terminals (TO) may include an external connection terminal TO configured with a ball bump and an external connection terminal TO configured with a columnar electrode.

(Aspects)

The following aspects are disclosed in the present specification.

According to a first aspect, a high frequency module (500; 500a; 500b) includes a mounting substrate (110), an antenna terminal (T1), a filter (1), and an inductor (4). The mounting substrate (110) has a first main surface (111) and a second main surface (112) that are opposite to each other. The antenna terminal (T1) is disposed on the mounting substrate (110). The filter (1) is connected to the antenna terminal (T1). The inductor (4) is disposed on the first main surface (111) of the mounting substrate (110). The inductor (4) includes a winding portion (413). The filter (1) has a plurality of acoustic wave resonators (14). The plurality of acoustic wave resonators (14) include a plurality of series arm resonators (S1 to S4) provided on a signal path (Ru1) connected to the antenna terminal (T1), and a plurality of parallel arm resonators (P1 to P4) connected between the signal path (Ru1) and a ground. When at least one of the series arm resonator (S1), which is closest to the antenna terminal (T1) among the plurality of series arm resonators (S1 to S4), and the parallel arm resonator (P1), which is closest to the antenna terminal (T1) among the plurality of parallel arm resonators (P1 to P4), is defined as an antenna end resonator (14A), the filter (1) includes a first substrate (substrate 10), a first functional electrode (11) provided on the first substrate and forming a part of the antenna end resonator (14A), a second substrate (substrate 20) separate from the first substrate, and a second functional electrode (21) provided on the second substrate and forming a part of at least one acoustic wave resonator (14) other than the antenna end resonator (14A) among the plurality of acoustic wave resonators (14). A first electronic component (E1) including the first substrate and the first functional electrode (11) is disposed on the first main surface (111) of the mounting substrate (110). A second electronic component (E2) including the second substrate and the second functional electrode (21) is disposed on the first main surface (111) of the mounting substrate (110). A distance between the antenna terminal (T1) and the first electronic component (E1) is shorter than a distance between the antenna terminal (T1) and the second electronic component (E2). The inductor (4) is adjacent to the first electronic component (E1) in a plan view from a thickness direction (D1) of the mounting substrate (110). The inductor (4) does not overlap the antenna end resonator (14A) in a side view from a direction of a winding axis (A4) of the winding portion (413).

According to the first aspect, the high frequency module (500; 500a; 500b) can reduce deterioration in characteristics of the filter (1).

According to a second aspect, a high frequency module (500; 500a; 500b) includes a mounting substrate (110), an antenna terminal (T1), a filter (1), and an inductor (4). The mounting substrate (110) has a first main surface (111) and a second main surface (112) that are opposite to each other. The antenna terminal (T1) is disposed on the mounting substrate (110). The filter (1) is connected to the antenna terminal (T1). The inductor (4) is disposed on the first main surface (111) of the mounting substrate (110). The inductor (4) includes a winding portion (413). The filter (1) has a plurality of acoustic wave resonators (14). The plurality of acoustic wave resonators (14) include a plurality of series arm resonators (S1 to S4) provided on a signal path (Ru1) connected to the antenna terminal (T1), and a plurality of parallel arm resonators (P1 to P4) connected between the signal path (Ru1) and a ground. When at least one of the series arm resonator (S1), which is closest to the antenna terminal (T1) among the plurality of series arm resonators (S1 to S4), and the parallel arm resonator (P1), which is closest to the antenna terminal (T1) among the plurality of parallel arm resonators (P1 to P4), is defined as an antenna end resonator (14A), the filter (1) includes a first substrate (substrate 10), a first functional electrode (11) provided on the first substrate and forming a part of the antenna end resonator (14A), a second substrate (substrate 20) separate from the first substrate, and a second functional electrode (21) provided on the second substrate and forming a part of at least one acoustic wave resonator (14) other than the antenna end resonator (14A) among the plurality of acoustic wave resonators (14). A first electronic component (E1) including the first substrate and the first functional electrode (11) is disposed on the first main surface (111) of the mounting substrate (110). A second electronic component (E2) including the second substrate and the second functional electrode (21) is disposed on the first main surface (111) of the mounting substrate (110). A distance between the antenna terminal (T1) and the first electronic component (E1) is shorter than a distance between the antenna terminal (T1) and the second electronic component (E2). The inductor (4) is adjacent to the first electronic component (E1) in a plan view from a thickness direction (D1) of the mounting substrate (110). In the inductor (4), the antenna end resonator (14A) does not overlap an inner part (414) of the winding portion (413) of the inductor (4) in a side view from a side opposite to a side of the first electronic component (E1).

According to the second aspect, the high frequency module (500; 500a; 500b) can reduce deterioration in characteristics of the filter (1).

According to a third aspect, in the first or second aspect, the high frequency module (500; 500a; 500b) further includes a second filter (2) having a second pass band different from a first pass band, which is a pass band of the first filter (1) serving as the filter (1). A second filter (2) has a plurality of second acoustic wave resonators (24) different from a plurality of first acoustic wave resonators (14), which are the plurality of acoustic wave resonators (14) of the first filter (1). A first electronic component (E1) includes a first substrate (substrate 10). A second electronic component (E2) includes a second substrate (substrate 20). The second filter (2) includes a third substrate (substrate 10). The first substrate is common to the third substrate.

According to the third aspect, the high frequency module (500; 500a; 500b) can include the antenna end resonator (14A) of the first filter (1) of the first electronic component (E1) and the second filter (2).

In the high frequency module (500; 500a; 500b) according to a fourth aspect, in the third aspect, the first pass band includes a frequency band of a first communication band. The second pass band includes a frequency band of a second communication band that enables simultaneous communication with the first communication band.

According to the fourth aspect, the high frequency module (500; 500a; 500b) can suppress deterioration in characteristics of the first filter (1) during simultaneous communication using the first filter (1) and the second filter (2).

In the high frequency module (500; 500a; 500b) according to a fifth aspect, in the third or fourth aspect, the at least one antenna end resonator (14A) is the parallel arm resonator (P1) that is closest to the antenna terminal (T1).

According to the fifth aspect, the high frequency module (500; 500a; 500b) can suppress deterioration in attenuation characteristics of the filter (1).

In the high frequency module (500; 500b) according to a sixth aspect, in any one of the first to fifth aspects, the mounting substrate (110) includes a first ground conductor portion (115) and the second ground conductor portion (116). At least a part of the first ground conductor portion (115) overlaps the first electronic component (E1) in a plan view from the thickness direction (D1) of the mounting substrate (110). At least a part of the second ground conductor portion (116) overlaps the second electronic component (E2) in a plan view from the thickness direction (D1) of the mounting substrate (110). A ratio of an area of a part overlapping the first ground conductor portion (115) to an area of the first electronic component (E1) is greater than a ratio of an area of a part overlapping the second ground conductor portion (116) to an area of the second electronic component (E2), in a plan view from the thickness direction (D1) of the mounting substrate (110).

According to the sixth aspect, the high frequency module (500; 500b) can easily dissipate heat generated in the first electronic component (E1), and can suppress a temperature increase in the first electronic component (E1).

In the high frequency module (500; 500b) according to a seventh aspect, in any one of the first to fifth aspects, the mounting substrate (110) includes a first ground conductor portion (115) and the second ground conductor portion (116). At least a part of the first ground conductor portion (115) overlaps the first electronic component (E1) in a plan view from the thickness direction (D1) of the mounting substrate (110). At least a part of the second ground conductor portion (116) overlaps the second electronic component (E2) in a plan view from the thickness direction (D1) of the mounting substrate (110). An area of a part of the first ground conductor portion (115) overlapping the first electronic component (E1) is larger than an area of a part of the second ground conductor portion (116) overlapping the second electronic component (E2), in a plan view from the thickness direction (D1) of the mounting substrate (110).

According to the seventh aspect, the high frequency module (500; 500b) can easily dissipate heat generated in the first electronic component (E1), and can suppress a temperature increase in the first electronic component (E1).

In the high frequency module (500a) according to an eighth aspect, in any one of the first to fifth aspects, the mounting substrate (110) includes a first ground conductor portion (115) and the second ground conductor portion (116). At least a part of the first ground conductor portion (115) overlaps the first electronic component (E1) in a plan view from the thickness direction (D1) of the mounting substrate (110). At least a part of the second ground conductor portion (116) overlaps the second electronic component (E2) in a plan view from the thickness direction (D1) of the mounting substrate (110). A ratio of an area of a part overlapping the second ground conductor portion (116) to an area of the second electronic component (E2) is greater than a ratio of an area of a part overlapping the first ground conductor portion (115) to an area of the first electronic component (E1), in a plan view from the thickness direction (D1) of the mounting substrate (110).

According to the eighth aspect, the high frequency module (500a) can easily dissipate heat generated in the second electronic component (E2), and can suppress a temperature increase in the second electronic component (E2).

In the high frequency module (500a) according to a ninth aspect, in any one of the first to fifth aspects, the mounting substrate (110) includes a first ground conductor portion (115) and the second ground conductor portion (116). At least a part of the first ground conductor portion (115) overlaps the first electronic component (E1) in a plan view from the thickness direction (D1) of the mounting substrate (110). At least a part of the second ground conductor portion (116) overlaps the second electronic component (E2) in a plan view from the thickness direction (D1) of the mounting substrate (110). An area of a part of the second ground conductor portion (116) overlapping the second electronic component (E2) is larger than an area of a part of the first ground conductor portion (115) overlapping the first electronic component (E1), in a plan view from the thickness direction (D1) of the mounting substrate (110).

According to the ninth aspect, the high frequency module (500a) can easily dissipate heat generated in the second electronic component (E2), and can suppress a temperature increase in the second electronic component (E2).

According to a tenth aspect, in any one of the first to ninth aspects, the high frequency module (500; 500a; 500b) further includes a resin layer (120) and a metal electrode layer (130). The resin layer (120) is disposed on the first main surface (111) of the mounting substrate (110), and covers at least a part of the first electronic component (E1), at least a part of the second electronic component (E2), and the inductor (4). The metal electrode layer (130) covers at least a part of the resin layer (120) and has a ground potential. A main surface of the second electronic component (E2) on a side opposite to the side of the mounting substrate (110) (second main surface 20B of the substrate 20) is in contact with the metal electrode layer (130).

According to the tenth aspect, the high frequency module (500; 500a; 500b) can easily dissipate heat generated in the second electronic component (E2).

According to an eleventh aspect, in any one of the first to ninth aspects, the high frequency module (500; 500a; 500b) further includes a resin layer (120) and a metal electrode layer (130). The resin layer (120) is disposed on the first main surface (111) of the mounting substrate (110), and covers at least a part of the first electronic component (E1), at least a part of the second electronic component (E2), and the inductor (4). The metal electrode layer (130) covers at least a part of the resin layer (120) and has a ground potential. A main surface of the first electronic component (E1) on a side opposite to the side of the mounting substrate (110) (second main surface 10B of the substrate 10) is in contact with the metal electrode layer (130).

According to the eleventh aspect, the high frequency module (500; 500a; 500b) can easily dissipate heat generated in the first electronic component (E1).

According to a twelfth aspect, a communication device (600) includes the high frequency module (500; 500a; 500b) and a signal processing circuit (601). The signal processing circuit (601) is connected to the high frequency module (500; 500a; 500b).

According to the twelfth aspect, the communication device (600) can suppress deterioration in characteristics of the filter (1).

### REFERENCE SIGNS LIST

1 Filter (first filter)
2 Second filter
4 Inductor
400 Element body
401 Top surface
402 Bottom surface
403 First side surface
404 Second side surface
405 Third side surface
406 Fourth side surface
411 First outer electrode
412 Second outer electrode
413 Winding portion
414 Inner part
A4 Winding axis
5 Inductor
60 to 69 Filter
60A Antenna end resonator
61A Antenna end resonator
62A Antenna end resonator
64A Antenna end resonator
7 Switch (first switch)
70 Common terminal
71 to 74 Selection terminal
8 IC chip
80 to 89 Low noise amplifier
9 Second switch
9A Common terminal
90 to 99 Selection terminal
10 Substrate
10A First main surface
10B Second main surface
11 First functional electrode
12 Piezoelectric film (first piezoelectric film)
13 Upper electrode (first upper electrode)
14 Acoustic wave resonator (first acoustic wave resonator)
14A Antenna end resonator (first antenna end resonator)
16 Cavity
17 IDT electrode
170 Intersection region
171 First electrode finger
172 Second electrode finger
18 Input/output terminal
19 Input/output terminal
20 Substrate
20A First main surface
20B Second main surface
21 Second functional electrode
22 Piezoelectric film (second piezoelectric film)
23 Upper electrode (second upper electrode)
26 Cavity
24 Acoustic wave resonator (second acoustic wave resonator)
24A Antenna end resonator (second antenna end resonator)
27 IDT electrode
271 First electrode finger
272 Second electrode finger
28 Input/output terminal
29 Input/output terminal
30 Substrate
31 Third functional electrode
32 Piezoelectric film (third piezoelectric film)
33 Upper electrode (third upper electrode)
36 Cavity
37 IDT electrode
371 First electrode finger
372 Second electrode finger
40 Substrate
50 Substrate
100 Support substrate (first support substrate)
101 High velocity member (first high velocity member)
102 Low velocity film (first low velocity film)
103 High velocity film (first high velocity film)
104 Piezoelectric layer (first piezoelectric layer)
107 Piezoelectric substrate (first piezoelectric substrate)
110 Mounting substrate
111 First main surface
112 Second main surface
113 Outer peripheral surface
115 First ground conductor portion
116 Second ground conductor portion
120 Resin layer (first resin layer)
130 Metal electrode layer
150 Second resin layer
200 Support substrate (second support substrate)
201 High velocity member (second high velocity member)
202 Low velocity film (second low velocity film)
203 High velocity film (second high velocity film)
204 Piezoelectric layer (second piezoelectric layer)
207 Piezoelectric substrate (second piezoelectric substrate)
500, 500a, 500b High frequency module
600 Communication device
601 Signal processing circuit
602 RF signal processing circuit
603 Baseband signal processing circuit
610 Antenna
D1 Thickness direction
E1 First electronic component
E2 Second electronic component
E3 Third electronic component
E4 Fourth electronic component
E5 Fifth electronic component
K1 Connection point
K2 Connection point
K3 Connection point
K4 Connection point
L0 to L17 Inductor
M1 Matching circuit
M2 Matching circuit
M3 Matching circuit
M4 Matching circuit
Ru1 Signal path (first signal path)
Ru2 Signal path (second signal path)
S1, S2, S3, S4, S5 Series arm resonator
S21, S22, S23, S24 vertically coupled resonator
S31, S32, S33, S34. S35 Series Arm Resonator
P1, P2, P3, P4 Parallel arm resonator
P31, P32, P33, P34 Parallel arm resonator
T0 External connection terminal
T1 Antenna terminal
T2 Signal output terminal
T3 External ground terminal
W1 Distance
W2 Distance
W17 Intersecting width

1. A high frequency module comprising:
a mounting substrate having a first main surface and a second main surface that are opposite to each other;
an antenna terminal on the mounting substrate;
a filter connected to the antenna terminal; and
an inductor on the first main surface of the mounting substrate and comprising a winding portion,
wherein the filter comprises a plurality of acoustic wave resonators,
wherein the plurality of acoustic wave resonators comprise:
a plurality of series arm resonators in a signal path connected to the antenna terminal, and
a plurality of parallel arm resonators connected between the signal path and ground,
wherein the series arm resonator and/or the parallel arm resonator closest to the antenna terminal is an antenna end resonator,
wherein the filter further comprises:
a first substrate,
a first functional electrode on the first substrate and forming a part of the antenna end resonator,
a second substrate separate from the first substrate, and
a second functional electrode on the second substrate and forming a part of at least one acoustic wave resonator other than the antenna end resonator,
wherein a first electronic component comprising the first substrate and the first functional electrode is on the first main surface of the mounting substrate,
wherein a second electronic component comprising the second substrate and the second functional electrode is on the first main surface of the mounting substrate,
wherein a distance between the antenna terminal and the first electronic component is shorter than a distance between the antenna terminal and the second electronic component,
wherein the inductor is adjacent to the first electronic component in a plan view from a thickness direction of the mounting substrate, and
wherein the inductor does not overlap the antenna end resonator in a side view from a direction of a winding axis of the winding portion.

2. A high frequency module comprising:
a mounting substrate having a first main surface and a second main surface that are opposite to each other;
an antenna terminal on the mounting substrate;
a filter connected to the antenna terminal; and
an inductor on the first main surface of the mounting substrate and comprising a winding portion,
wherein the filter comprises a plurality of acoustic wave resonators,
wherein the plurality of acoustic wave resonators comprise:
a plurality of series arm resonators in a signal path connected to the antenna terminal, and
a plurality of parallel arm resonators connected between the signal path and ground,
wherein a series arm resonator and/or a parallel arm resonator closest to the antenna terminal is an antenna end resonator,
wherein the filter further comprises:
a first substrate,
a first functional electrode on the first substrate and forming a part of the antenna end resonator,
a second substrate separate from the first substrate, and
a second functional electrode on the second substrate and forming a part of at least one acoustic wave resonator other than the antenna end resonator,
wherein a first electronic component comprising the first substrate and the first functional electrode is on the first main surface of the mounting substrate,
wherein a second electronic component comprising the second substrate and the second functional electrode is on the first main surface of the mounting substrate,
wherein a distance between the antenna terminal and the first electronic component is shorter than a distance between the antenna terminal and the second electronic component,
wherein the inductor is adjacent to the first electronic component in a plan view from a thickness direction of the mounting substrate, and
wherein in the inductor, the antenna end resonator does not overlap an inner part of the winding portion of the inductor in a side view from a side opposite to a side of the first electronic component.

3. The high frequency module according to claim 1, further comprising:
a second filter having a second pass band different from a first pass band of the filter,
wherein the second filter has a plurality of second acoustic wave resonators different from the plurality of first acoustic wave resonators of the filter,
wherein the second filter comprises a third substrate, and
wherein the first substrate is common to the third substrate.

4. The high frequency module according to claim 2, further comprising:
a second filter having a second pass band different from a first pass band of the filter,
wherein the second filter has a plurality of second acoustic wave resonators different from the plurality of first acoustic wave resonators of the filter,
wherein the second filter comprises a third substrate, and
wherein the first substrate is common to the third substrate.

5. The high frequency module according to claim 3,
wherein the first pass band comprises a frequency band of a first communication band, and
wherein the second pass band comprises a frequency band of a second communication band that enables simultaneous communication with the first communication band.

6. The high frequency module according to claim 4,
wherein the first pass band comprises a frequency band of a first communication band, and
wherein the second pass band comprises a frequency band of a second communication band that enables simultaneous communication with the first communication band.

7. The high frequency module according to claim 3, wherein the at least one antenna end resonator is the parallel arm resonator closest to the antenna terminal.

8. The high frequency module according to claim 4, wherein the at least one antenna end resonator is the parallel arm resonator closest to the antenna terminal.

9. The high frequency module according to claim 1,
wherein the mounting substrate comprises:
a first ground conductor, at least a part of which overlaps the first electronic component in the plan view, and
a second ground conductor, at least a part of which overlaps the second electronic component in the plan view, and
wherein in the plan view, a ratio of an area of the overlapping part of the first ground conductor to an area of the first electronic component is greater than a ratio of an area of the overlapping part of the second ground conductor to an area of the second electronic component.

10. The high frequency module according to claim 2,
wherein the mounting substrate comprises:
a first ground conductor, at least a part of which overlaps the first electronic component in the plan view, and
a second ground conductor, at least a part of which overlaps the second electronic component in the plan view, and
wherein in the plan view, a ratio of an area of the overlapping part of the first ground conductor to an area of the first electronic component is greater than a ratio of an area of the overlapping part of the second ground conductor to an area of the second electronic component.

11. The high frequency module according to claim 1,
wherein the mounting substrate comprises:
a first ground conductor, at least a part of which overlaps the first electronic component in the plan view, and
a second ground conductor, at least a part of which overlaps the second electronic component in the plan view, and
wherein in the plan view, an area of the part of the first ground conductor overlapping the first electronic component is larger than an area of the part of the second ground conductor overlapping the second electronic component.

12. The high frequency module according to claim 2,
wherein the mounting substrate comprises:
a first ground conductor, at least a part of which overlaps the first electronic component in the plan view, and
a second ground conductor, at least a part of which overlaps the second electronic component in the plan view, and
wherein in the plan view, an area of the part of the first ground conductor overlapping the first electronic component is larger than an area of the part of the second ground conductor overlapping the second electronic component.

13. The high frequency module according to claim 1,
wherein the mounting substrate comprises:
a first ground conductor, at least a part of which overlaps the first electronic component in the plan view, and
a second ground conductor, at least a part of which overlaps the second electronic component in the plan view, and
wherein in the plan view, a ratio of an area of the overlapping part of the second ground conductor to an area of the second electronic component is greater than a ratio of an area of the overlapping part of the first ground conductor to an area of the first electronic component.

14. The high frequency module according to claim 2,
wherein the mounting substrate comprises:
a first ground conductor, at least a part of which overlaps the first electronic component in the plan view, and
a second ground conductor, at least a part of which overlaps the second electronic component in the plan view, and
wherein in the plan view, a ratio of an area of the overlapping part of the second ground conductor to an area of the second electronic component is greater than a ratio of an area of the overlapping part of the first ground conductor to an area of the first electronic component.

15. The high frequency module according to claim 1,
wherein the mounting substrate comprises:
a first ground conductor, at least a part of which overlaps the first electronic component in the plan view, and
a second ground conductor, at least a part of which overlaps the second electronic component in the plan view, and
wherein in the plan view, an area of the part of the second ground conductor overlapping the second electronic component is larger than an area of the part of the first ground conductor overlapping the first electronic component.

16. The high frequency module according to claim 2,
wherein the mounting substrate comprises:
a first ground conductor, at least a part of which overlaps the first electronic component in the plan view, and
a second ground conductor, at least a part of which overlaps the second electronic component in the plan view, and
wherein in the plan view, an area of the part of the second ground conductor overlapping the second electronic component is larger than an area of the part of the first ground conductor overlapping the first electronic component.

17. The high frequency module according to claim 1, further comprising:
a resin layer on the first main surface of the mounting substrate that covers at least a part of the first electronic component, at least a part of the second electronic component, and the inductor; and
a metal electrode layer that covers at least a part of the resin layer and that has a ground potential,
wherein a main surface of the second electronic component, which is on a side of the high frequency module opposite to a side of the mounting substrate, is in contact with the metal electrode layer.

18. The high frequency module according to claim 2, further comprising:
a resin layer on the first main surface of the mounting substrate that covers at least a part of the first electronic component, at least a part of the second electronic component, and the inductor; and
a metal electrode layer that covers at least a part of the resin layer and that has a ground potential,
wherein a main surface of the second electronic component, which is on a side of the high frequency module opposite to a side of the mounting substrate, is in contact with the metal electrode layer.

19. The high frequency module according to claim 1, further comprising:
a resin layer on the first main surface of the mounting substrate that covers at least a part of the first electronic component, at least a part of the second electronic component, and the inductor; and
a metal electrode layer that covers at least a part of the resin layer and that has a ground potential,
wherein a main surface of the first electronic component, which is on a side of the high frequency module opposite to a side of the mounting substrate, is in contact with the metal electrode layer.

20. The high frequency module according to claim 2, further comprising:
a resin layer on the first main surface of the mounting substrate that covers at least a part of the first electronic component, at least a part of the second electronic component, and the inductor; and
a metal electrode layer that covers at least a part of the resin layer and that has a ground potential,
wherein a main surface of the first electronic component, which is on a side of the high frequency module opposite to a side of the mounting substrate, is in contact with the metal electrode layer.
